(19) United States
(12) Patent Application Publication
(10) Pub. No.: US 2025/0052609 A1
(43) Pub. Date: Feb. 13, 2025

(54) LIGHT DETECTION DEVICE AND ELECTRONIC DEVICE

(71) Applicant: SONY SEMICONDUCTOR SOLUTIONS CORPORATION, KANAGAWA (JP)

(72) Inventor: KAZUHIRO GOI, KANAGAWA (JP)

(21) Appl. No.: 18/720,694

(22) PCT Filed: Dec. 14, 2022
(86) PCT No.: PCT/JP2022/046031

§ 371 Date: Jun. 17, 2024

(30) Foreign Application Priority Data
Dec. 27, 2021 (JP) 2021-212518

(51) Int. Cl. G01J 1/44

(52) U.S. Cl. CPC G01J 1/44; G01J 2001/446

(57) ABSTRACT

The present disclosure relates to a light detection device and an electronic device capable of reducing reflection of incident light depending on an image height position. The light detection device includes a pixel array unit in which a plurality of pixels is arranged in a two-dimensional array. Each pixel includes: a refractive index variation layer having at least two regions in the same layer, the two regions being a first region containing a first matter and a second region containing a second matter; and a photoelectric conversion unit that photoelectrically converts light incident through the refractive index variation layer. An effective refractive index of the refractive index variation layer is configured to differ depending on an image height position of the pixel. The present disclosure can be applied in, for example, a solid-state image capturing device, a light-receiving device of a rangefinding system, or the like.

### TECHNICAL FIELD

The present disclosure relates to a light detection device and an electronic device, and particularly relates to a light detection device and an electronic device capable of reducing reflection of incident light depending on an image height position.

### BACKGROUND ART

The refractive index of a silicon substrate used as a semiconductor substrate in a CMOS image sensor is high, and the difference from the refractive index of a color filter layer formed on an incident surface side of the silicon substrate is large. As such, when the color filter layer is formed directly on the silicon substrate, the difference in the refractive indices results in a large amount of the incident light being reflected. This reflection causes problems such as a drop in the quantum efficiency Qe and the occurrence of flaring.

In response to such problems, for example, PTL 1 discloses a technique for reducing the reflection of incident light by forming a moth-eye structure as an anti-reflection structure between the color filter layer and the silicon substrate.

### CITATION LIST

### Patent Literature

[PTL 1]
JP 2017-108062A

### SUMMARY

### Technical Problem

Incidentally, because the incident angle of incident light varies depending on the image height position, the reflection characteristics of the incident light also vary depending on the image height position. However, a pixel structure optimized according to the image height position has not been disclosed.

Having been conceived in view of such circumstances, the present disclosure makes it possible to reduce reflection of incident light depending on the image height position.

### Solution to Problem

A light detection device according to a first aspect of the present disclosure includes:
a pixel array unit in which a plurality of pixels is arranged in a two-dimensional array, each pixel including:
a refractive index variation layer having at least two regions in the same layer, the two regions being a first region containing a first matter and a second region containing a second matter; and
a photoelectric conversion unit that photoelectrically converts light incident through the refractive index variation layer,
wherein an effective refractive index of the refractive index variation layer is configured to differ depending on an image height position of the pixel.

An electronic device according to a second aspect of the present disclosure includes a light detection device,
wherein the light detection device includes a pixel array unit in which a plurality of pixels is arranged in a two-dimensional array, each pixel including:
a refractive index variation layer having at least two regions in the same layer, the two regions being a first region containing a first matter and a second region containing a second matter; and
a photoelectric conversion unit that photoelectrically converts light incident through the refractive index variation layer, and
wherein an effective refractive index of the refractive index variation layer is configured to differ depending on an image height position of the pixel.

In the first and second aspects of the present disclosure, a pixel array unit in which a plurality of pixels is arranged in a two-dimensional array is provided. Each pixel includes: a refractive index variation layer having at least two regions in the same layer, the two regions being a first region containing a first matter and a second region containing a second matter; and a photoelectric conversion unit that photoelectrically converts light incident through the refractive index variation layer. An effective refractive index of the refractive index variation layer is configured to differ depending on an image height position of the pixel.

The light detection device and the electronic device may be independent devices, or may be modules incorporated into a different device.

### BRIEF DESCRIPTION OF DRAWINGS

FIG. 1 is a cross-sectional view of a first embodiment of a pixel according to the present disclosure.

FIG. 2 is a plan view of a pixel array unit, illustrating image height positions.

FIG. 3 is a diagram illustrating results of simulations of refractive index variation layers.

FIG. 4 is a diagram illustrating a method for designing a refractive index variation layer.

FIG. 5 is a diagram illustrating pattern variations for a refractive index variation layer.

FIG. 6 is a diagram illustrating pattern variations for a refractive index variation layer.

FIG. 7 is a diagram illustrating pattern variations for a refractive index variation layer.

FIG. 8 is a cross-sectional view of a second embodiment of a pixel according to the present disclosure.

FIG. 9 is a cross-sectional view of a third embodiment of a pixel according to the present disclosure.

FIG. 10 is a cross-sectional view of a fourth embodiment of a pixel according to the present disclosure.

FIG. 11 is a cross-sectional view of a fifth embodiment of a pixel according to the present disclosure.

FIG. 12 is a diagram illustrating an example of application in a plurality of pixels under the same OCL.

FIG. 13 is a diagram illustrating an example of application in a plurality of pixels under the same OCL.

FIG. 14 is a block diagram illustrating an example of the overall configuration of a solid-state image capturing device to which the technique of the present disclosure is applied.

FIG. 15 is a block diagram illustrating an example of the configuration of an image capturing device serving as an electronic device to which the present technique is applied.

FIG. 16 is a diagram illustrating an example of the use of an image sensor.

FIG. 17 is a diagram illustrating an example of the schematic configuration of an endoscopic surgery system.

FIG. 18 is a block diagram illustrating an example of the functional configuration of a camera head and a CCU.

FIG. 19 is a block diagram illustrating an example of the schematic configuration of a vehicle control system.

FIG. 20 is an explanatory diagram illustrating an example of installation positions of a vehicle exterior information detecting unit and image capturing units.

### DESCRIPTION OF EMBODIMENTS

Modes for embodying the technique of the present disclosure (hereinafter referred to as “embodiments”) will be described below with reference to the accompanying drawings. The descriptions will be given in the following order.
1. First Embodiment of Pixel
2. Pattern Variations for Refractive Index Variation Layer
3. Second Embodiment of Pixel
4. Third Embodiment of Pixel
5. Fourth Embodiment of Pixel
6. Fifth Embodiment of Pixel
7. Example of Application to Plurality of Pixels Under Same OCL
8. Conclusion
9. Other Examples of Configuration of Photoelectric Conversion Unit
10. Example of Configuration of Solid-State Image Capturing Device
11. Example of Application in Electronic Device
12. Application in Light Detection Devices in General
13. Example of Application in Endoscopic Surgery System
14. Example of Application in Moving Body

In the drawings referred to in the following descriptions, the same or similar parts will be denoted by the same or similar reference signs, and redundant descriptions will be omitted. The drawings are schematic, and the relationships between thicknesses and planar dimensions, the ratios of thicknesses of layers, and the like are different from the actual ratios, thicknesses, and the like. The drawings may also include parts having dimensional relationships and ratios different from those in other drawings.

In addition, it is to be understood that definitions of directions such as up-down in the following descriptions are merely definitions provided for the sake of brevity and are not intended to limit the technical spirit of the present disclosure. For example, when an object is observed after being rotated by 90 degrees, “up-down” is transformed into “left-right”, and when an object is observed after being rotated by 180 degrees, “up-down” is inverted.

### 1. First Embodiment of Pixel

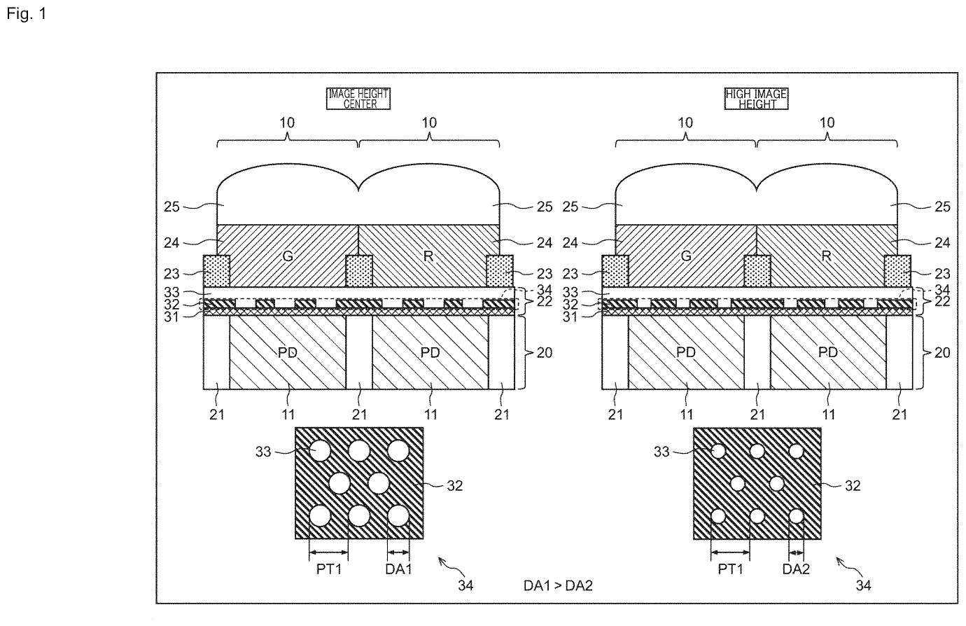

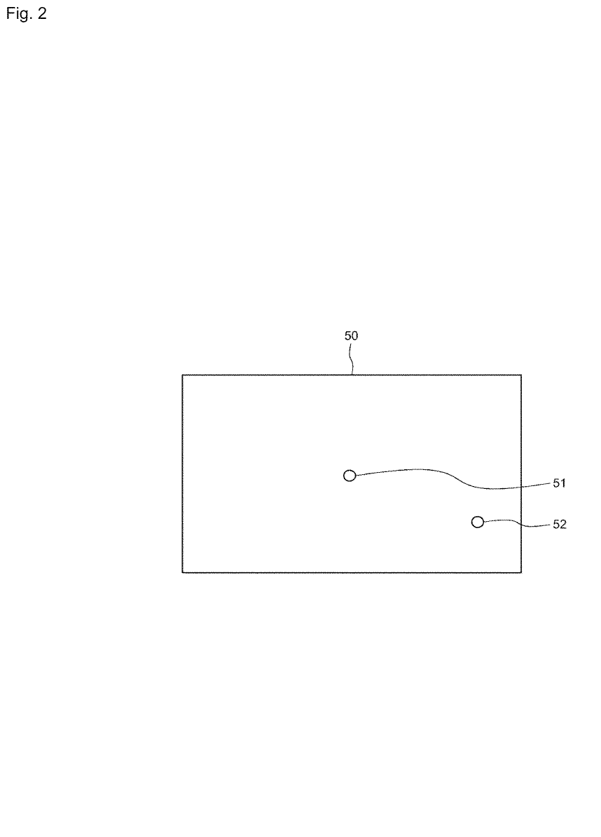

First, a first embodiment of a pixel according to the present disclosure will be described with reference to FIGS. 1 and 2.

FIG. 1 is a cross-sectional view of the first embodiment of a pixel according to the present disclosure.

FIG. 1 illustrates a cross-sectional view of two pixels 10 arranged in a row direction or a column direction, for both a position near an image height center and a high image height position. Here, the position near the center of the image height corresponds, for example, to a position 51 in a pixel array unit 50 illustrated in FIG. 2, and corresponds to a position close to the center of an effective pixel region, i.e., a position close to the center of the optical axis of an image capturing lens (not shown). On the other hand, the high image height position corresponds, for example, to a position 52 in a pixel array unit 50 in FIG. 2, and corresponds to a position close to the outer periphery of the effective pixel region. In the pixel array unit 50, the pixels 10 illustrated in FIG. 1 are arranged in a two-dimensional array, with the row direction referred to as the horizontal direction of the pixel array unit 50 and the column direction referred to as the vertical direction of the pixel array unit 50.

Each pixel 10 in FIG. 1 is formed on a semiconductor substrate 20 which uses silicon (Si) as a semiconductor material. Each pixel 10 has a photodiode (PD) 11 as a photoelectric conversion unit. In other words, the photodiode 11, which uses a PN junction between a P-type semiconductor region and an N-type semiconductor region formed on the semiconductor substrate 20, is formed on a pixel-by-pixel basis. A pixel separation part 21, which separates the photodiodes 11 formed in the respective pixels 10, is formed at pixel boundary parts of the semiconductor substrate 20. The pixel separation part 21 can be formed of an insulating film such as an oxide film, or a metal film such as tungsten (W), aluminum (Al), copper (Cu), titanium (Ti), molybdenum (Mo), nickel (Ni), or the like, for example. In addition, parts or all of the pixel separation part 21 may be formed of an air layer.

In the cross-sectional view in FIG. 1, an upper surface of the semiconductor substrate 20 is a rear surface of the semiconductor substrate 20 and is a light incident surface on which incident light is incident, and a lower surface of the semiconductor substrate 20 is a front surface of the semiconductor substrate 20. Although not illustrated, a plurality of pixel transistors, which read out charges accumulated in the photodiodes 11, and a multilayer wiring layer, which is constituted by a plurality of metal wiring layers and interlayer insulating films, are formed on the front surface side of the semiconductor substrate 20.

An anti-reflection film 22 constituted by a plurality of films is formed on the rear surface of the semiconductor substrate 20, which is the upper side in FIG. 1. In the example in FIG. 1, the anti-reflection film 22 is constituted by three layers, namely an aluminum oxide film (Al2O3) 31, a titanium oxide film (TiO2) 32, and a silicon oxide film (SiO2) 33, in that order from the side closer to the semiconductor substrate 20. The aluminum oxide film 31, which is the lowest of the three layers, is formed at a uniform film thickness. The silicon oxide film 33, which is the uppermost layer, is partially embedded in the titanium oxide film 32, which is the intermediate layer. In a partial region of the titanium oxide film 32 in the intermediate layer, the intermediate layer in which the upper-layer silicon oxide film 33 is embedded constitutes a refractive index variation layer 34 in which the effective refractive index with respect to incident light varies between the pixels 10 in the position near the center of the image height and the pixels 10 in the high image height position.

A plan view of (part of) the refractive index variation layer 34 is provided below the cross-sectional view of the pixel 10 in the position near the center of the image height and the cross-sectional view of the pixel 10 in the high image height position.

As illustrated in the plan view, the refractive index variation layer 34 is configured by combining the region of the titanium oxide film 32 and the region of the silicon oxide film 33. The titanium oxide film 32 constitutes the main region of the refractive index variation layer 34, and a plurality of the silicon oxide films 33 formed in circular shapes are disposed in a partial region of the titanium oxide film 32 at predetermined intervals.

Of the three layers constituting the anti-reflection film 22, the refractive index of the aluminum oxide film 31 is, for example, about 1.64; the refractive index of the titanium oxide film 32 is, for example, about 2.67; and the refractive index of the silicon oxide film 33 is, for example, about 1.46. The refractive index of silicon (Si), which constitutes the semiconductor substrate 20, is, for example, about 4.16.

When the structure in which the silicon oxide film 33 is embedded in the titanium oxide film 32 is formed to be sufficiently smaller than the wavelength of incident light, the effective refractive index of the refractive index variation layer 34 is determined by the average refractive index according to an area ratio between the refractive index of the titanium oxide film 32 and the refractive index of the silicon oxide film 33. Because the titanium oxide film 32 constitutes the main region of the refractive index variation layer 34, the effective refractive index of the refractive index variation layer 34 is a refractive index greater than both the lower layer aluminum oxide film 31 and the upper-layer silicon oxide film 33. Instead of the titanium oxide film 32, tantalum oxide (Ta2O5) or the like, for example, may be used as an intermediate layer having a higher refractive index than the upper and lower layers. The refractive index of tantalum oxide film (Ta2O5) is, for example, about 2.35. In the present embodiment, the refractive index variation layer 34 is formed in a high refractive index layer of the three layers stacked with the refractive indices thereof being “low-high-low”, but the refractive index variation layer 34 may be formed in a low refractive index layer. In other words, the refractive index variation layer 34 may be formed by embedding a high refractive index layer in a part of a low refractive index layer of the anti-reflection film 22, which is constituted by a plurality of films having different refractive indices. An air layer (air gap) may also be used as the high refractive index layer or the low refractive index layer.

The pattern size of the silicon oxide film 33 formed having circular shapes is different between the pixels 10 in the position near the center of the image height and the pixels 10 in the high image height position. Specifically, if the pattern of the silicon oxide film 33 in the refractive index variation layer 34 at the pixel 10 in the position near the center of the image height is circles each having a diameter DA1, the pattern of the silicon oxide film 33 in the refractive index variation layer 34 at the pixel 10 in the high image height position is circles each having a diameter DA2 smaller than the diameter DA1 (DA1>DA2).

As such, the effective refractive index of the refractive index variation layer 34 is higher in the pixels 10 in the high image height position, where the ratio of the titanium oxide film 32 having a high refractive index is higher, than the pixels 10 in the position near the center of the image height.

A pitch (interval) PT1 of the silicon oxide film 33 formed as circles is the same for the pixels 10 in the position near the center of the image height and the pixels 10 in the high image height position. However, as will be described later, the pitch of the silicon oxide film 33 may be different between the pixels 10 in the position near the center of the image height and the pixels 10 in the high image height position. The pitch PT1 of the silicon oxide film 33 is formed to be a pitch smaller than the wavelength of the incident light that passes through the refractive index variation layer 34 and is incident on the photodiodes 11.

An inter-pixel light shielding film 23 is formed in the pixel boundary part on the upper side of the anti-reflection film 22 in the cross-sectional view. The inter-pixel light shielding film 23 is formed as a lattice when seen in plan view. The inter-pixel light shielding film 23 may be any material that shields light, but a material that has strong light shielding properties and can be accurately processed through microfabrication, such as etching, for example, is desirable. The inter-pixel light shielding film 23 can be formed of a metal film such as tungsten (W), aluminum (Al), copper (Cu), titanium (Ti), molybdenum (Mo), nickel (Ni), or the like, for example. The inter-pixel light shielding film 23 may be formed of an oxide film or a resin film having a low refractive index, an air layer, or the like.

A color filter layer 24 that transmits light of a corresponding one of R (red), G (green), or B (blue) colors (wavelengths) is formed on a pixel-by-pixel basis in the regions on the anti-reflection film 22 aside from the inter-pixel light shielding film 23. The color filter layer 24 is formed by rotationally applying a photosensitive resin containing a colorant such as a pigment or a dye, for example. The R, G, and B color filter layers 24 are provided as a Bayer array, for example, but may be provided using another arrangement method. In the example in FIG. 1, the G color filter layer 24 is formed in the left pixel 10 among the two pixels, and the R color filter layer 24 is formed in the right pixel 10. Accordingly, the two pixels illustrated in FIG. 1 correspond to a part of a row or column of pixels in the Bayer array in which G pixels that receive incident light of the G wavelength and R pixels that receive incident light of the R wavelength are disposed in an alternating manner.

An on-chip lens 25 is formed for each pixel above the color filter layer 24. The on-chip lens 25 focuses the light entering the pixel 10 onto the photodiode 11 in the semiconductor substrate 20. The on-chip lens 25 is formed of, for example, a resin material such as a styrene resin, an acrylic resin, a styrene-acrylic copolymer resin, or a siloxane resin.

Each pixel 10 in FIG. 1 has the configuration described above, and light incident through the on-chip lens 25, the color filter layer 24, and the refractive index variation layer 34 is incident on the photodiode 11 of the semiconductor substrate 20, and is photoelectrically converted.

Because the refractive index of the semiconductor substrate 20 on which the photodiode 11 is formed is high (the refractive index of the silicon is, for example, about 4.16), when the color filter layer 24 is formed directly on the semiconductor substrate 20, the difference in refractive indices between the semiconductor substrate 20 and the color filter layer 24 is high, and a large amount of incident light is reflected due to the refractive index difference. This reflection causes problems such as a drop in the quantum efficiency Qe and the occurrence of flaring.

Accordingly, in the pixel 10, an anti-reflection film 22 is formed between the color filter layer 24 and the semiconductor substrate 20 in order to reduce the reflection of incident light at the interface of the semiconductor substrate 20. The anti-reflection film 22 is configured by layering the silicon oxide film 33, the titanium oxide film 32, and the aluminum oxide film 31 in that order from the upper layer on the color filter layer 24 side. The refractive indices of the silicon oxide film 33, the titanium oxide film 32, and the aluminum oxide film 31 are “low-high-low.”

The refractive index variation layer 34 is configured by embedding the upper-layer silicon oxide film 33 in a part of a planar region of the titanium oxide film 32 in the intermediate layer, which has a high refractive index. The effective refractive index of the refractive index variation layer 34 is configured to be different depending on the pixel position in the pixel array unit 50.

Specifically, in the refractive index variation layer 34, the area ratio between the titanium oxide film 32 and the silicon oxide film 33 in the pixel 10 in the position near the center of the image height is different from the area ratio between the titanium oxide film 32 and the silicon oxide film 33 in the pixel 10 in the high image height position. The ratio of the titanium oxide film 32 having a higher refractive index is higher in the high image height position than in the position near the center of the image height. Conversely, the ratio of the silicon oxide film 33 having a lower refractive index is lower in the high image height position than in the position near the center of the image height.

An incident angle (CRA) of the incident light relative to the semiconductor substrate 20 is small in the position near the center of the image height, which is near the center of the optical axis, but increases as the image height increases, and then decreases after peaking at the predetermined high image height position. When the incident angle increases and the incident light becomes oblique, the reflection characteristics of the incident light shift toward the short-wavelength side, resulting in what is known as “blue shift”. In the refractive index variation layer 34, the ratio of the titanium oxide film 32 is higher at the high image height position than at the position near the center of the image height, and the effective refractive index is higher at the high image height position than at the position near the center of the image height, which cancels out the blue shift.

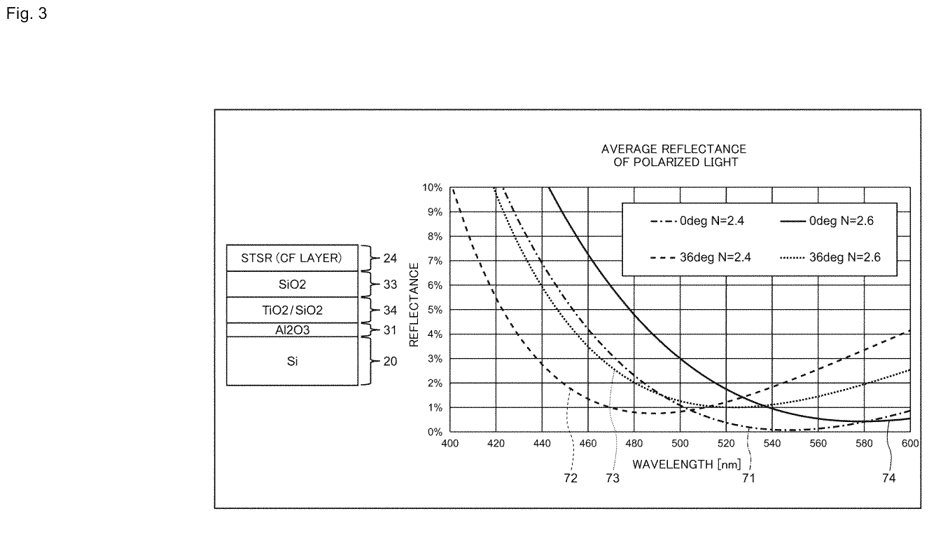

FIG. 3 illustrates an example of the results of simulations for the refractive index variation layer 34.

In the simulation, the inventors assumed a layered structure including the semiconductor substrate (silicon layer) 20, the aluminum oxide film 31, the refractive index variation layer 34 constituted by the titanium oxide film 32 and the silicon oxide film 33, the silicon oxide film 33, and the color filter layer (STSR) 24, as illustrated in the layer cross-sectional view on the left, and calculated the light reflection characteristics (reflectance). The color filter layer 24 was assumed to transmit incident light of the G wavelength, and the refractive index of the refractive index variation layer 34 was assumed to have no wavelength dependence for the sake of simplicity.

A reflection characteristic graph 71 represents a case where the refractive index of the refractive index variation layer 34 (the average refractive index of the titanium oxide film 32 and the silicon oxide film 33) is 2.4 and the incident angle is 0 degrees, or in other words, indicates a relationship between the wavelength and the reflectance of incident light for the pixel 10 in the image height center. The reflection characteristic graph 71 is adjusted such that the reflectance is low around 530 to 550 nm, which corresponds to the G wavelength.

A reflection characteristic graph 72 represents a case where the refractive index of the refractive index variation layer 34 is also 2.4 and the incident angle is 36 degrees, or in other words, indicates a relationship between the wavelength and the reflectance of incident light for the pixel 10 in the high image height position. The reflection characteristic graph 72 represents a relationship between the wavelength and the reflectance of the incident light in which the wavelength has an extremely small point at about 490 nm. Accordingly, the pixel position changing from the image height center to the high image height position results in the reflection characteristics shifting in the short wavelength direction from the reflection characteristic graph 71 to the reflection characteristic graph 72, i.e., a blue shift.

Accordingly, assume that the refractive index of the refractive index variation layer 34 has been changed to 2.6 by changing the area ratio of the titanium oxide film 32 and the silicon oxide film 33. A reflection characteristic graph 73 represents a case where the refractive index of the refractive index variation layer 34 is 2.6 and the incident angle is 36 degrees, or in other words, indicates a relationship between the wavelength and the reflectance of incident light for the pixel 10 in the high image height position. The reflection characteristic graph 73 represents a relationship between the wavelength and the reflectance of the incident light in which the wavelength has an extremely small point at about 520 nm. In other words, increasing the refractive index of the refractive index variation layer 34 from 2.4 to 2.6 cancels out the blue shift.

For comparative purposes, a reflection characteristic graph 74 represents a case where the refractive index of the refractive index variation layer 34 is 2.6 and the incident angle is 0 degrees, or in other words, indicates a relationship between the wavelength and the reflectance of incident light for the pixel 10 in the image height center.

On the basis of these simulation results, it can be seen that varying the refractive index of the refractive index variation layer 34 between the image height center and the high image height position makes it possible to handle differences in the incident angle depending on the image height position, and reduce the reflection of incident light.

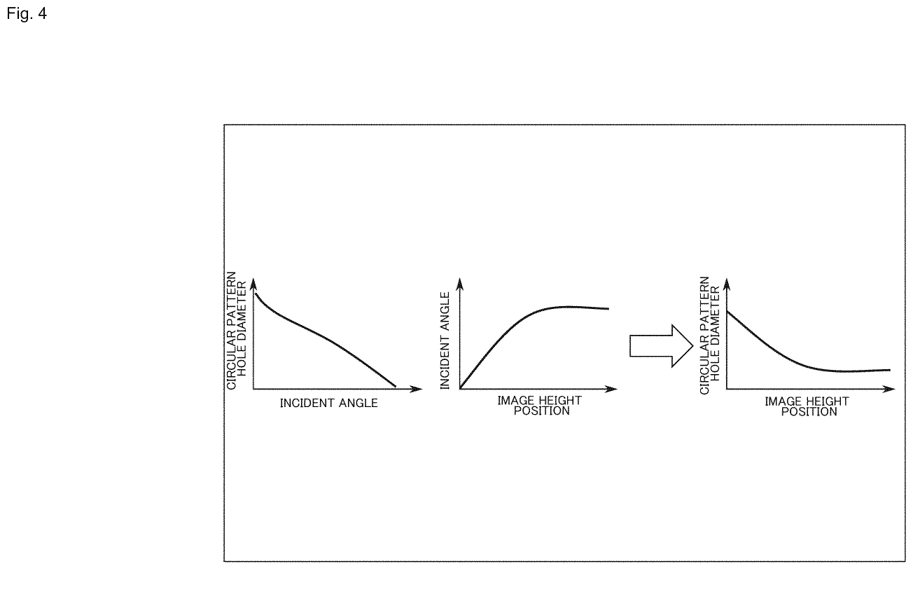

A method for designing the refractive index variation layer 34 will be described with reference to FIG. 4.

First, an optimal effective refractive index is calculated according to the incident angle of the incident light. When the pattern shape of the silicon oxide film 33 is circular and the pitch PT1 of the circular pattern is set to a predetermined pitch smaller than the wavelength of the incident light, the diameter of the circular pattern (a hole diameter) is set corresponding to the calculated effective refractive index. As such, the relationship between the incident angle and the diameter of the silicon oxide film 33 having the circular pattern (the hole diameter), illustrated on the left side in FIG. 4, can be obtained.

The relationship between the image height position and the incident angle of the light rays in the pixel array unit 50 can also be calculated. Accordingly, the relationship between the image height position and the diameter of the circular pattern of the silicon oxide film 33 (the hole diameter), illustrated on the right side in FIG. 4, can be calculated from (i) the relationship between the incident angle and the diameter of the circular pattern (the hole diameter) and (ii) the relationship between the image height position and the incident angle. Through this, the diameter of the circular pattern of the silicon oxide film 33 (the hole diameter) can be determined according to the image height position.

### 2. Pattern Variations for Refractive Index Variation Layer

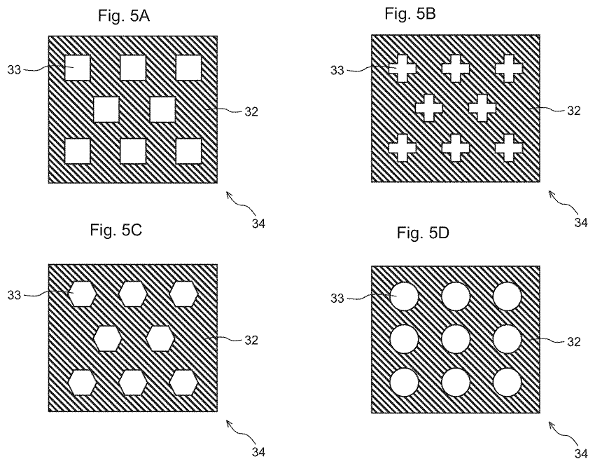

FIGS. 5 to 7 illustrate variations on the planar patterns of the titanium oxide film 32 and the silicon oxide film 33 constituting the refractive index variation layer 34.

In the refractive index variation layer 34 of the pixel 10 illustrated in FIG. 1, the circular silicon oxide film 33 is disposed in a plurality of parts in the titanium oxide film 32.

However, the pattern shape of the silicon oxide film 33 is not limited to circles, and may be other shapes instead. For example, the pattern shape may be quadrangles as illustrated in A of FIG. 5, or may be triangles (not shown). The pattern shape may be crosses as illustrated in B of FIG. 5, hexagons as illustrated in C of FIG. 5, or the like.

In addition, the arrangement pattern of the silicon oxide film 33 is not limited to the example in FIG. 1. In the example in FIG. 1, the silicon oxide film 33 is arranged in what is known as a hexagonal close-packed arrangement, in which the circular pattern of the silicon oxide film 33 is shifted by half a pitch in adjacent rows or columns.

However, for example, the pattern may be an arrangement pattern in which the silicon oxide film 33 having a predetermined shape is arranged in a matrix, as illustrated in D of FIG. 5. Although D in FIG. 5 is an example in which the pattern shape of the silicon oxide film 33 is circles, other shapes such as those mentioned above may of course be used instead.

The planar shape and arrangement pattern of the silicon oxide film 33 is not particularly limited, and any shape and arrangement can be used. As such, the refractive index can be set to a desired value, and a planar shape and arrangement pattern that are easy to manufacture (process) can be selected. This makes it possible to improve the degree of freedom by which the refractive index can be changed, and makes the manufacturing process easier.

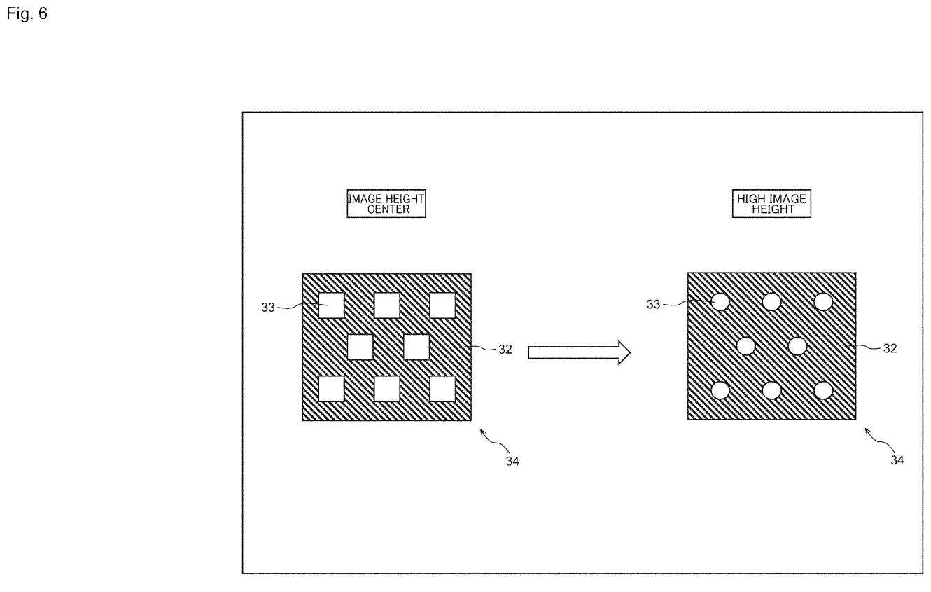

In addition, the pattern shape of the silicon oxide film 33 formed in the titanium oxide film 32 need not be the same pattern shape in all regions of the pixel array unit 50, and different pattern shapes may be formed depending on the image height position. For example, as illustrated in FIG. 6, the silicon oxide film 33 pattern shape may be formed as squares in the position near the center of the image height, and may be formed as circles in the high image height position. The difference in the shapes may be formed intentionally or unintentionally.

In the arrangement of the silicon oxide film 33 in FIG. 6, the pattern shape is different depending on the image height position, but the pitch of the pattern is the same in the position near the center of the image height and the high image height position. However, the pitch of the pattern may be different between the position near the center of the image height and the high image height position. That said, to suppress scattering of the incident light, it is desirable that the pitch of the pattern be no greater than the wavelength of the incident light.

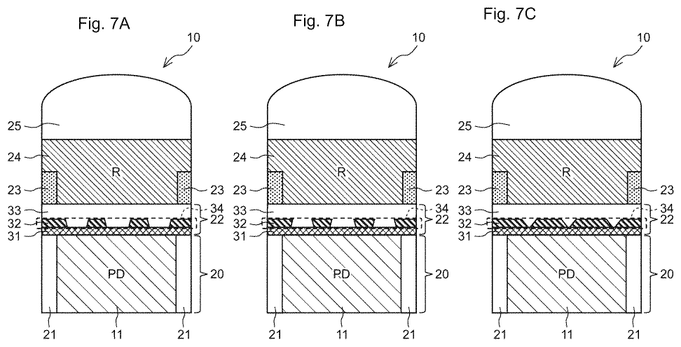

Furthermore, the pattern shape of the silicon oxide film 33 formed in the refractive index variation layer 34 may be formed such that the cross-section is angled, as indicated in the cross-sectional views in A to C of FIG. 7.

A in FIG. 7 indicates an example in which the circular pattern of the silicon oxide film 33 of the refractive index variation layer 34 is formed in a tapered shape such that the planar area thereof is greater on the lower-layer side than on the upper-layer side.

B in FIG. 7 indicates an example in which the circular pattern of the silicon oxide film 33 of the refractive index variation layer 34 is formed in a reverse-tapered shape such that the planar area thereof is smaller on the lower-layer side than on the upper-layer side.

C in FIG. 7 illustrates an example in which the silicon oxide film 33 of the refractive index variation layer 34 is formed in the shape of a cone or polygonal trapezoid having a point on the side where the aluminum oxide film 31, which is the lower layer, is located.

As illustrated in the cross-sectional views in A to C of FIG. 7, when the area ratio between the titanium oxide film 32 and the silicon oxide film 33 varies in the thickness direction, the effective refractive index of the refractive index variation layer 34 also varies in the thickness direction. As such, the effective refractive index of the refractive index variation layer 34 is calculated as being different depending on the depth position of the refractive index variation layer 34.

Furthermore, the planar pattern shape of the silicon oxide film 33 may be formed to differ depending on the depth position in the refractive index variation layer 34.

### 3. Second Embodiment of Pixel

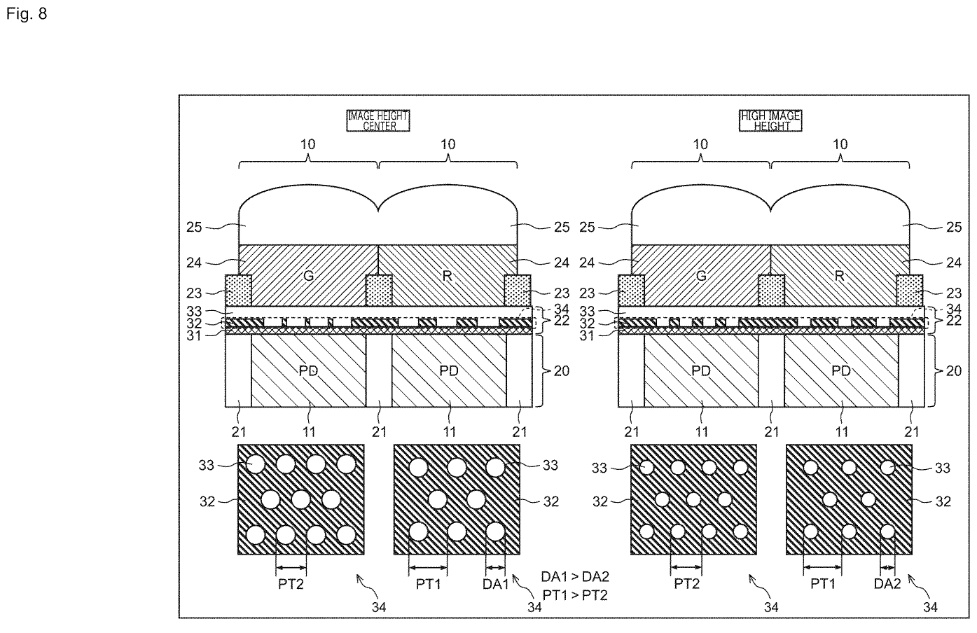

FIG. 8 is a cross-sectional view of the second embodiment of a pixel according to the present disclosure.

Like FIG. 1, FIG. 8 illustrates a cross-sectional view of the configurations of two pixels, for the position near the center of the image height and the high image height position, respectively, as well as plan views of the refractive index variation layer 34. In FIG. 8, parts that are the same as in the first embodiment, illustrated in FIG. 1, are given the same reference signs, and descriptions of those parts will be omitted as appropriate, with parts different from those in the first embodiment being described.

In the first embodiment described above, the ratio of the silicon oxide film 33 disposed in the titanium oxide film 32 was changed according to the image height position such that the effective refractive index of the refractive index variation layer 34 is optimized according to the incident angle of the incident light. More specifically, the diameter DA of the silicon oxide film 33 having the circular pattern is assumed to be the diameter DA1 in the pixel 10 at the position near the center of the image height, and the diameter DA2, which is smaller than the diameter DA1 (DA1>DA2) in the pixel 10 at the high image height position.

On the other hand, in the refractive index variation layer 34 in the first embodiment described above, there is no difference in refractive index according to the color (transmission wavelength) of the color filter layer 24.

In contrast, in the second embodiment, the effective refractive index of the refractive index variation layer 34 is adjusted to be optimal according not only to the incident angle of the incident light, but also to the wavelength of the incident light received by each pixel 10, i.e., the color of the color filter layer 24.

Specifically, the wavelengths of the incident light incident on the pixel 10 where the R color filter layer 24 is formed (also called an “R pixel” hereinafter as appropriate), the pixel 10 where the G color filter layer 24 is formed (also called a “G pixel” hereinafter as appropriate), and the pixel 10 where the B color filter layer 24 is formed (also called a “B pixel” hereinafter as appropriate) are in a magnitude relationship of B pixel<G pixel<R pixel. As the wavelength of the incident light becomes shorter, it is necessary to reduce the refractive index, and it is therefore necessary to increase the ratio of the silicon oxide film 33, which has a lower refractive index, in the refractive index variation layer 34.

Accordingly, in the second embodiment illustrated in FIG. 8, the ratio of the silicon oxide film 33 of the G pixel is made higher than that of the R pixel by setting a pitch PT2 of the G pixels, in the silicon oxide film 33 having the circular pattern, to be smaller than the pitch PT1 of the R pixels. As a result, the effective refractive index of the refractive index variation layer 34 for the G pixels is adjusted to be lower than the effective refractive index of the refractive index variation layer 34 for the R pixels.

In other words, the diameter DA and the pitch PT of the circular pattern of the silicon oxide film 33 in the refractive index variation layer 34 in the position near the center of the image height are the diameter DA1 and the pitch PT1 in the R pixel, but are the diameter DA1 and the pitch PT2 (PT2<PT1) in the G pixel.

The diameter DA and the pitch PT of the circular pattern of the silicon oxide film 33 in the refractive index variation layer 34 in the high image height position are the diameter DA2 and the pitch PT1 in the R pixel, but are the diameter DA2 and the pitch PT2 (PT2<PT1) in the G pixel.

In other words, for the R pixel, the diameter DA1 and the pitch PT1 in the position near the center of the image height, and the diameter DA2 and the pitch PT1 in the high image height position are the same as in the first embodiment, but in the second embodiment, the pitch PT of the circular pattern of the silicon oxide film 33 in the G pixel is changed from the pitch PT1 of the first embodiment to the pitch PT2.

Although not illustrated, in the rows or columns in which the B pixels and the R pixels are arranged in an alternating manner, the pitch PT1 of the B pixels is changed to a pitch PT3 that is smaller than the pitch PT2 of the G pixels (PT3<PT2<PT1).

As described above, each pixel 10 in the second embodiment has the refractive index variation layer 34 in which the effective refractive index is optimized according to the incident angle and wavelength of the incident light. The refractive index variation layer 34 is configured by combining the region of the titanium oxide film 32 and the region of the silicon oxide film 33. This makes it possible to reduce the reflection of the incident light in accordance with differences in the incident angle depending on the image height position, as well as differences in the wavelength.

### 4. Third Embodiment of Pixel

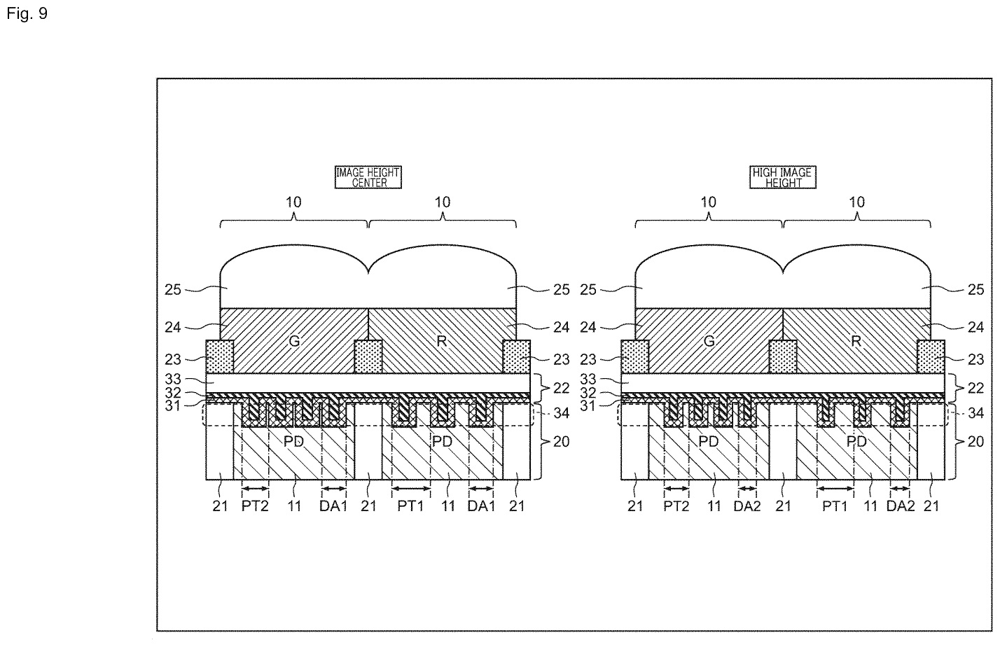

FIG. 9 is a cross-sectional view of a third embodiment of a pixel according to the present disclosure.

Like FIG. 1, FIG. 9 also illustrates a cross-sectional view of the configurations of two pixels, for the position near the center of the image height and the high image height position, respectively. In FIG. 9, parts that are the same as in the first embodiment, illustrated in FIG. 1, are given the same reference signs, and descriptions of those parts will be omitted as appropriate, with parts different from those in the first embodiment being described.

In the first embodiment illustrated in FIG. 1, the refractive index variation layer 34 was formed by embedding the upper-layer silicon oxide film 33 in a part of a planar region of the titanium oxide film 32, which is the intermediate layer of the three layers constituting the anti-reflection film 22.

In contrast, in the third embodiment, the refractive index variation layer 34 is formed by embedding the titanium oxide film 32 and the aluminum oxide film 31, which are the intermediate and lower layers of the three layers constituting the anti-reflection film 22, respectively, in a region within the semiconductor substrate 20 in which the photodiode 11 is formed (called a “PD formation region” hereinafter). In other words, the refractive index variation layer 34 is configured by combining (i) the PD formation region and (ii) the region of the aluminum oxide film 31 and the titanium oxide film 32.

Although the plan view of the refractive index variation layer 34 is omitted, the pattern shapes of the aluminum oxide film 31 and the titanium oxide film 32 embedded in the PD formation region are a circular pattern (circles), as in the first embodiment. As described as a variation on the first embodiment, the pattern shapes of the aluminum oxide film 31 and the titanium oxide film 32 embedded in the PD formation region may be shapes other than a circular pattern.

For the diameter DA of the circular pattern of the aluminum oxide film 31 and the titanium oxide film 32 in the R pixel, the magnitude relationship between the position near the center of the image height and the high image height position is the same as in the first embodiment. In other words, the diameter is assumed to be the diameter DA1 in the position near the center of the image height, and the diameter DA2, which is smaller than the diameter DA1 (DA1>DA2), in the high image height position.

As described above, the refractive index of silicon (Si), which constitutes the semiconductor substrate 20, is, for example, about 4.16; the refractive index of the aluminum oxide film 31 is, for example, about 1.64; and the refractive index of the titanium oxide film 32 is, for example, about 2.67. As such, the higher the ratio of the PD formation region (silicon) is, the greater the effective refractive index of the refractive index variation layer 34 becomes.

Accordingly, of the position near the center of the image height and the high image height position, the effective refractive index of the refractive index variation layer 34 is higher in the high image height position than in the position near the center of the image height for the R pixel.

In addition, in the third embodiment, the effective refractive index of the refractive index variation layer 34 is optimally adjusted according to the wavelength of the incident light, as in the second embodiment.

Specifically, the pitch PT of the circular pattern of the aluminum oxide film 31 and the titanium oxide film 32 is the pitch PT1 in the R pixel, but is the pitch PT2, which is smaller than the pitch PT1 (PT2<PT1), in the G pixel. In the G pixel, the diameter DA of the circular pattern of the aluminum oxide film 31 and the titanium oxide film 32 is the diameter DA1 in the position near the center of the image height, and the diameter DA2 in the high image height position.

Accordingly, the circular pattern of the aluminum oxide film 31 and the titanium oxide film 32 is formed such that the effective refractive index of the refractive index variation layer 34 is lower for the G pixels than for the R pixels, as in the second embodiment.

As described above, each pixel 10 in the third embodiment has the refractive index variation layer 34 in which the effective refractive index is optimized according to the incident angle and wavelength of the incident light. The refractive index variation layer 34 is configured by combining (i) the PD formation region, (ii) the aluminum oxide film 31 region, and (iii) the titanium oxide film 32 region. This makes it possible to reduce the reflection of the incident light in accordance with differences in the incident angle depending on the image height position, as well as differences in the wavelength.

Note that in the third embodiment, the refractive index variation layer 34 may be configured to have no difference according to the color (transmission wavelength) of the color filter layer 24, as in the first embodiment.

In addition, depending on the diameters DA1 and DA2, the material embedded in the PD formation region of the refractive index variation layer 34 may be only the aluminum oxide film 31, rather than two layers, i.e., the aluminum oxide film 31 and the titanium oxide film 32.

### 5. Fourth Embodiment of Pixel

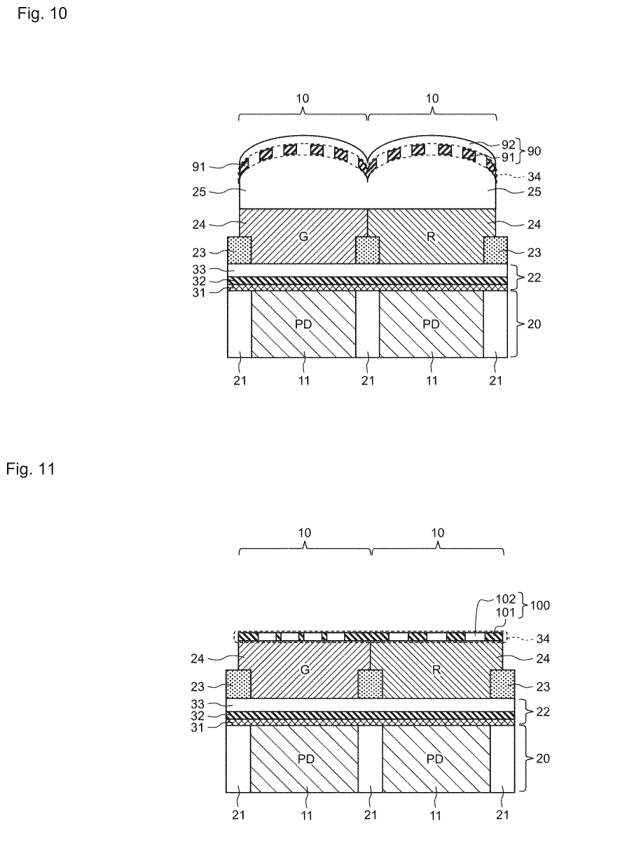

FIG. 10 is a cross-sectional view of a fourth embodiment of a pixel according to the present disclosure.

FIG. 10 also illustrates a cross-sectional view of the configuration of two pixels arranged in predetermined positions in the pixel array unit 50. In FIG. 10, parts that are the same as in the first embodiment, illustrated in FIG. 1, are given the same reference signs, and descriptions of those parts will be omitted as appropriate, with parts different from those in the first embodiment being described.

The fourth embodiment differs from the foregoing first embodiment in that the refractive index variation layer 34 is formed in a layer of an anti-reflection film 90 formed on the uppermost surface of the on-chip lens 25, rather than in a layer of the anti-reflection film 22 on the semiconductor substrate 20.

The anti-reflection film 90 formed on the upper surface of the on-chip lens 25 is constituted by layering a first film 91 and a second film 92. Like the anti-reflection film 22, a tantalum oxide film (Ta2O5), an aluminum oxide film (Al2O3), a titanium oxide film (TiO2), or the like, for example, can be used for the first film 91 and the second film 92. A silicon oxide film, a silicon nitride film, or a silicon oxynitride film, or a resin material such as a styrene resin, an acrylic resin, a styrene-acrylic copolymer resin, a siloxane resin, or the like, may also be used for the first film 91 and the second film 92. One of the first film 91 and the second film 92 may be formed from the same material as the on-chip lens 25.

The upper-layer second film 92 is embedded in a partial region of the lower-layer first film 91. The lower-layer first film 91 is constituted, for example, by a material having a higher refractive index than the upper-layer second film 92. In other words, the refractive index variation layer 34 is configured by combining a region of the first film 91 having a high refractive index and a region of the second film 92 having a lower refractive index. The first film 91 constitutes the main region of the refractive index variation layer 34, and a plurality of the second films 92 formed in a predetermined pattern shape are disposed in a partial region of the first film 91 at predetermined intervals.

The ratio of the first film 91 and the second film 92 in the refractive index variation layer 34 is different between the pixel 10 in the position near the center of the image height and the pixel 10 in the high image height position. In other words, the effective refractive index of the refractive index variation layer 34 is adjusted to an optimal value according to the image height position, and the density of the first film 91 in the pixel 10 at the high image height position is higher than in the pixel 10 at the position near the center of the image height.

Furthermore, like the second embodiment, in the fourth embodiment, the effective refractive index of the refractive index variation layer 34 may be adjusted so as to be optimized according not only to the incident angle of the incident light, but also the wavelength of the incident light received by each pixel 10.

In the fourth embodiment, by forming the refractive index variation layer 34 on the uppermost surface of the on-chip lens 25, each of the three layers constituting the anti-reflection film 22, specifically, the aluminum oxide film 31 in the lowermost layer, the titanium oxide film 32 in the intermediate layer, and the silicon oxide film 33 in the uppermost layer, is formed on the entire region of the pixel array unit 50 at a uniform film thickness.

The configuration of the pixel 10 aside from the above-described points is the same as in the first embodiment and will therefore not be described.

As described above, each pixel 10 in the fourth embodiment has the refractive index variation layer 34, in which the effective refractive index is optimized according to the incident angle of the incident light, formed on the uppermost surface of the on-chip lens 25. The refractive index variation layer 34 is configured by combining a region of the first film 91 and a region of the second film 92 having different refractive indices. This makes it possible to reduce the reflection of the incident light in accordance with differences in the incident angle depending on the image height position. In addition, when the effective refractive index of the refractive index variation layer 34 is adjusted to be optimal in accordance with the wavelength of the incident light received by each pixel 10 as well, the reflection of the incident light can be reduced also in accordance with differences in the wavelength.

### 6. Fifth Embodiment of Pixel

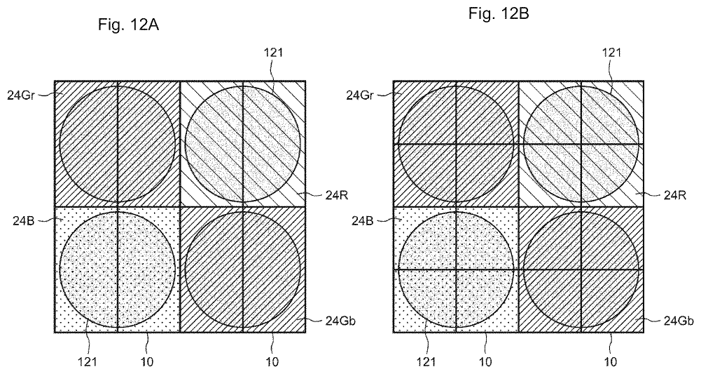

FIG. 11 is a cross-sectional view of a fifth embodiment of a pixel according to the present disclosure.

FIG. 11 also illustrates a cross-sectional view of the configuration of two pixels arranged in predetermined positions in the pixel array unit 50. In FIG. 11, parts that are the same as in the first embodiment, illustrated in FIG. 1, are given the same reference signs, and descriptions of those parts will be omitted as appropriate, with parts different from those in the first embodiment being described.

The fifth embodiment differs from the foregoing first embodiment in that the refractive index variation layer 34 is formed in a layer of an anti-reflection film 100 formed above the color filter layer 24, rather than in a layer of the anti-reflection film 22 on the semiconductor substrate 20.

The anti-reflection film 100 formed on an upper surface of the color filter layer 24 is constituted by a combination of a region of a first film 101 and a region of a second film 102. The first film 101 is constituted, for example, by a material having a higher refractive index than the second film 102. The first film 101 is constituted, for example, by a titanium oxide film, a tantalum oxide film, or the like, as in the first embodiment, and the second film 102 is constituted, for example, by a silicon oxide film, a silicon nitride film, a silicon oxynitride film, or the like.

In other words, the refractive index variation layer 34 is configured by combining a region of the first film 101 having a high refractive index and a region of the second film 102 having a lower refractive index. The first film 101 constitutes the main region of the refractive index variation layer 34, and a plurality of the second films 102 formed in a predetermined pattern shape are disposed in a partial region of the first film 101 at predetermined intervals.

The ratio of the first film 101 and the second film 102 in the refractive index variation layer 34 is different between the pixel 10 in the position near the center of the image height and the pixel 10 in the high image height position. The effective refractive index of the refractive index variation layer 34 is adjusted to an optimal value according to the image height position, and the density of the first film 101 in the pixel 10 at the high image height position is higher than in the pixel 10 at the position near the center of the image height.

Furthermore, like the second embodiment, in the fifth embodiment, the effective refractive index of the refractive index variation layer 34 may be adjusted so as to be optimized according not only to the incident angle of the incident light, but also the wavelength of the incident light received by each pixel 10.

In the fifth embodiment, by forming the refractive index variation layer 34 on the upper surface of the color filter layer 24, the three layers constituting the anti-reflection film 22 are formed on the entire region of the pixel array unit 50 at a uniform film thickness. In addition, the on-chip lens 25 formed above the color filter layer 24 in the first embodiment is omitted.

The configuration of the pixel 10 aside from the above-described points is the same as in the first embodiment and will therefore not be described.

As described above, each pixel 10 in the fifth embodiment has the refractive index variation layer 34, in which the effective refractive index is optimized according to the incident angle of the incident light, formed on the upper surface of the color filter layer 24. The refractive index variation layer 34 is configured by combining a region of the first film 101 and a region of the second film 102 having different refractive indices. This makes it possible to reduce the reflection of the incident light in accordance with differences in the incident angle depending on the image height position. In addition, when the effective refractive index of the refractive index variation layer 34 is adjusted to be optimal in accordance with the wavelength of the incident light received by each pixel 10 as well, the reflection of the incident light can be reduced also in accordance with differences in the wavelength.

The on-chip lens 25 omitted in the fifth embodiment and illustrated in FIG. 11 may be provided rather than being omitted.

### 7. Example of Application to Plurality of Pixels Under Same OCL

Each of the foregoing embodiments described an example in which the on-chip lens 25 is formed in units of pixels, and the effective refractive index of the refractive index variation layer 34 is varied depending on the incident angle of the incident light, which changes depending on the image height position in the pixel array unit 50. In other words, examples were described in which the effective refractive index of the refractive index variation layer 34 is caused to correspond to a different incident angle for the center area of the image height and the high image height position.

Incidentally, some solid-state image capturing devices have a structure in which one on-chip lens is provided for a plurality of adjacent pixels.

For example, there is a structure in which the pixel 10 has a rectangular pixel shape, and one on-chip lens 121 is provided for two pixels 10 adjacent in the row direction, as indicated by A in FIG. 12.

In addition, for example, there is a structure in which the pixel 10 has a square pixel shape, and one on-chip lens 121 is provided for a total of four pixels 10 in a 2×2 arrangement, with two pixels arranged in each of the row direction and the column direction, as indicated by B in FIG. 12.

For the color filter layer 24, a color filter layer 24 of the same color is provided for the plurality of pixels on which one on chip lens 121 is provided. In the pixel structure indicated in A of FIG. 12, a Gr (green) color filter layer 24Gr, a R (red) color filter layer 24R, a B (blue) color filter layer 24B, and a Gb (green) color filter layer 24Gb are provided in a Bayer array, in units of two pixels. In the pixel structure indicated in B of FIG. 12, a Gr color filter layer 24Gr, a R color filter layer 24R, a B color filter layer 24B, and a Gb color filter layer 24Gb are provided in a Bayer array, in units of four, i.e., 2×2, pixels. The color filter layers 24Gr and 24Gb are G (green) color filter layers 24G of the same color, and differ in terms of whether the color filter layer 24 of another color provided in the same row is the R color filter layer 24R or the B color filter layer 24B. The color filter layer 24Gr is a G color filter layer 24G in which the R color filter layer 24R is provided in the same row, and the color filter layer 24Gb is a G color filter layer 24G in which the B color filter layer 24B is provided in the same row.

In such a pixel structure, when signals from a plurality of pixels under the one on-chip lens 121 are read out at the same time for all the pixels, those signals can be used as a pixel signal of a single pixel having a large pixel size. On the other hand, when signals from a plurality of pixels under the one on-chip lens 121 are read out individually, those signals can be used as phase difference signals.

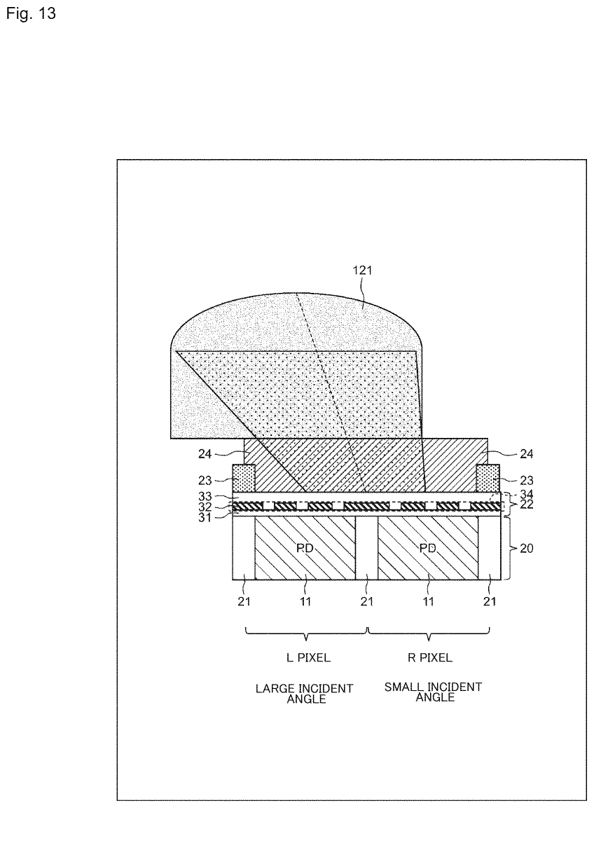

In addition, such a pixel structure has a feature in that the incident angle of the incident light is different for each pixel under the one on-chip lens 121 at the high image height position. For example, with the pixel structure in which one on-chip lens 121 is provided for the two rectangular pixels indicated in A of FIG. 12, the incident light enters the pixel 10 on the right (an R pixel) from the right side of the on-chip lens 121, and enters the pixel 10 on the left (an L pixel) from the left side of the on-chip lens 121, as illustrated in FIG. 13, and thus the incident angles are different. Accordingly, in the refractive index variation layer 34 provided for each pixel 10 under the one on-chip lens 121, the refractive index variation layer 34 can be adjusted so that the effective refractive index is optimal according to the difference in the incident angle resulting from the difference in the position of the on-chip lens 121 through which the incident light passes. This makes it possible to reduce the reflection of the incident light in accordance with differences in the incident angle of the light incident on each pixel 10 under the one on-chip lens 121.

### 8. Summary

The pixel 10 in each of the foregoing embodiments includes the refractive index variation layer 34 having at least two regions in the same layer, a first region containing a first matter, and a second region containing a second matter having a refractive index different from the first matter. The effective refractive index of the refractive index variation layer 34 is configured to differ depending on the image height position of the pixel 10. Specifically, the area ratio between the first region and the second region in the refractive index variation layer 34 is adjusted according to the incident angle of the incident light, which differs depending on the image height position.

In the foregoing first embodiment, for example, the first region is a region of the titanium oxide film 32, in which the first matter is titanium oxide, and the second region is a region of the silicon oxide film 33, in which the second matter is silicon oxide. The refractive index variation layer 34 may be configured by using air for one of the first matter or the second matter, and such that the first region or the second region is an air layer, by forming an air layer region and an oxide film region in the same layer, for example.

In addition, for example, as in the third embodiment illustrated in FIG. 9, the refractive index variation layer 34 may also be configured having three regions in the same layer, namely, the first region containing the first matter, the second region containing the second matter having a different refractive index from the first matter, and a third region containing a third matter having a different refractive index from the first and second matters. In the third embodiment, for example, the first region is a PD formation region, in which the first matter is silicon; the second region is a region of the aluminum oxide film 31, in which the second matter is aluminum oxide; and the third region is a region of the titanium oxide film 32, in which the third matter is titanium oxide.

Providing the pixel 10 with the refractive index variation layer 34 makes it possible to reduce the reflection of incident light depending on the image height position. Reducing the reflection of the incident light makes it possible to increase the amount of transmitted light, which in turn makes it possible to increase the quantum efficiency Qe and suppress the occurrence of flaring.

### 9. Other Examples of Configuration of Photoelectric Conversion Unit

The foregoing embodiments have described an example in which the photodiode 11, serving as a photoelectric conversion unit, is configured in the semiconductor substrate 20 formed of silicon (Si).

However, the material of the semiconductor substrate 20 is not limited to silicon. For example, the material of the semiconductor substrate 20 may be germanium (Ge), a compound semiconductor having a chalcopyrite structure such as SiGe, GaAs, InGaAs, InGaAsP, InAs, InSb, InAsSb, or the like, or a III-V compound semiconductor, and the photodiode 11 may be configured therein.

### 10. Example of Configuration of Solid-State Image Capturing Device

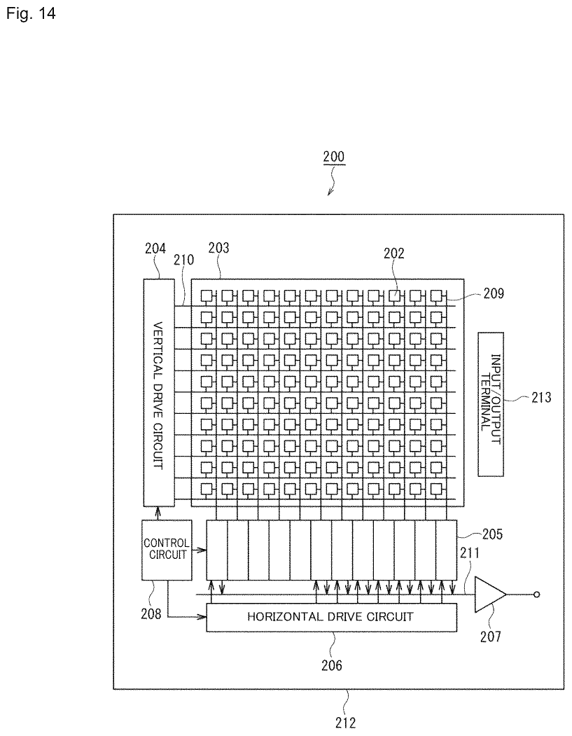

FIG. 14 is a block diagram illustrating an example of the overall configuration of a solid-state image capturing device to which the technique of the present disclosure is applied and which includes the above-described pixel 10.

A solid-state image capturing device 200 in FIG. 14 is configured including a pixel array unit 203 having pixels 202 arranged in a two-dimensional array on a semiconductor substrate 212 using silicon (Si), for example, as a semiconductor, and a peripheral circuit unit in the periphery thereof. The peripheral circuit unit includes a vertical drive circuit 204, column signal processing circuits 205, a horizontal drive circuit 206, an output circuit 207, a control circuit 208, and the like.

Each of the pixels 202 arranged in a two-dimensional array in the pixel array unit 203 has any one of the configurations of the first to fifth embodiments of the pixel 10 described above. In other words, the pixel 202 includes the refractive index variation layer 34 in which the effective refractive index is varied at least according to the image height position, and has a pixel structure in which reflection of incident light is reduced according to the image height position.

The control circuit 208 receives an input clock, data instructing an operation mode, and the like, and outputs data such as internal information of the solid-state image capturing device 200. In other words, the control circuit 208 generates clock signals and control signals as references for the operations of the vertical drive circuit 204, the column signal processing circuits 205, and the horizontal drive circuit 206 based on vertical synchronization signals, horizontal synchronization signals, and a master clock. The control circuit 208 then outputs the generated clock signal or control signal to the vertical drive circuit 204, the column signal processing circuits 205, the horizontal drive circuit 206, and the like.

The vertical drive circuit 204, which is constituted by, for example, a shift register, drives the pixels 202 in units of rows by selecting a predetermined pixel driving wire 210 and supplying a pulse for driving the pixels 202 to the selected pixel driving wire 210. That is, the vertical drive circuit 204 sequentially performs selection scanning on the pixels 202 in the pixel array unit 203 in the vertical direction in units of rows, and supplies a pixel signal based on signal charges generated in accordance with the amount of light received in the photoelectric conversion unit of each of the pixels 202 to the column signal processing circuits 205 through vertical signal lines 209.

One column signal processing circuit 205 is provided for each column of the pixels 202, and performs signal processing such as noise cancellation on a signal output from the pixels 202 corresponding to one row for each column. For example, the column signal processing circuit 205 performs signal processing such as correlated double sampling (CDS) and AD conversion for removing pixel-specific fixed pattern noise.

The horizontal drive circuit 206, which is constituted by, for example, a shift register, sequentially outputs a horizontal scanning pulse to select each of the column signal processing circuits 205 in order, and outputs a pixel signal to a horizontal signal line 211 from each of the column signal processing circuits 205.

The output circuit 207 performs predetermined signal processing on the signals sequentially supplied from the respective column signal processing circuits 205 through the horizontal signal line 211, and outputs the resulting signals. For example, the output circuit 207 may perform only buffering in some cases, or may perform black level adjustment, column variation compensation, and various kinds of digital signal processing in other cases. An input/output terminal 213 exchanges signals with the exterior.

The solid-state image capturing device 200 configured as described above is a CMOS image sensor, known as a column AD type, in which the column signal processing circuits 205 that perform CDS processing and AD conversion processing are provided on a column-by-column basis. In addition, the solid-state image capturing device 200 includes the pixel 10 configured as described above as the pixels 202 of the pixel array unit 203.

By using the pixel 10 configured as described above as the pixels 202 of the pixel array unit 203, the solid-state image capturing device 200 can reduce reflection of incident light in each pixel 202, and can therefore generate a high-quality captured image.

### 11. Example of Application in Electronic Device

The technique of the present disclosure (the present technique) is not limited to being applied in a solid-state image capturing device. In other words, the present technique can be applied in electronic devices in general in which a solid-state image capturing device is used in an image capturing unit (a photoelectric conversion unit), including image capturing devices such as digital still cameras and video cameras, mobile terminal devices having image capturing functions, copiers which use solid-state image capturing devices as image reading units, and the like. The solid-state image capturing device may be formed as a single chip, or may be formed as a module having an image capturing function, in which an image capturing unit and a signal processing unit or an optical system are packaged together.

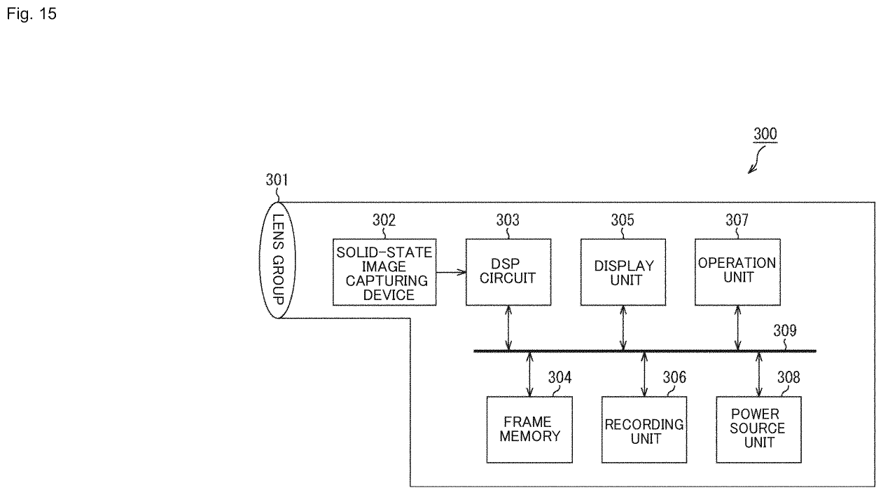

FIG. 15 is a block diagram illustrating an example of the configuration of an image capturing device serving as an electronic device to which the present technique is applied.

An image capturing device 300 in FIG. 15 includes an optical unit 301 constituted by a lens group and the like, a solid-state image capturing device (an image capturing device) 302 having the configuration of the solid-state image capturing device 200 in FIG. 14, and a digital signal processor (DSP) circuit 303 serving as a camera signal processing circuit. The image capturing device 300 also includes a frame memory 304, a display unit 305, a recording unit 306, an operation unit 307, and a power source unit 308. The DSP circuit 303, the frame memory 304, the display unit 305, the recording unit 306, the operation unit 307, and the power source unit 308 are connected to each other by a bus line 309.

The optical unit 301 captures incident light (image light) from a subject and forms an image on an image forming surface of the solid-state image capturing device 302. The solid-state image capturing device 302 converts the amount of incident light formed as an image on the image forming surface by the optical unit 301 into an electrical signal for each pixel, and outputs the electrical signal as a pixel signal. The solid-state image capturing device 302 can have the configuration of the solid-state image capturing device 200 in FIG. 14, i.e., the configuration of the pixel 10 described above as the pixels 202 in the pixel array unit 203, and can use a solid-state image capturing device which reduces reflection of incident light.

The display unit 305 includes, for example, a panel-type display device such as a liquid crystal panel or an organic EL (Electro Luminescence) panel, and displays moving images or still images captured by the solid-state image capturing device 302. The recording unit 306 records the moving images or the still images captured by the solid-state image capturing device 302 in a recording medium such as a hard disk or a semiconductor memory.

The operation unit 307 issues operation commands for various functions of the image capturing device 300 in response to operations by a user. The power source unit 308 appropriately supplies various types of power serving as operation power for the DSP circuit 303, the frame memory 304, the display unit 305, the recording unit 306, and the operation unit 307, to those units.

As described above, by using the solid-state image capturing device 302 having the pixel 10 configured as described above as the pixels that receive incident light from the subject, i.e., the pixel structure including the refractive index variation layer 34 for which the effective refractive index differs according to differences in the incident angle depending on the image height position, reflection of the incident light can be reduced, and a drop in image quality can be suppressed, for example. In addition, increasing the quantum efficiency Qe and suppressing the occurrence of flaring makes it possible to improve the S/N ratio and achieve a high dynamic range. Accordingly, a high captured image quality can be achieved in images captured by the image capturing device 300 employed in a video camera, a digital still camera, and furthermore, in a camera module for a mobile device, including a mobile phone.

### <Usage Example of Image Sensor>

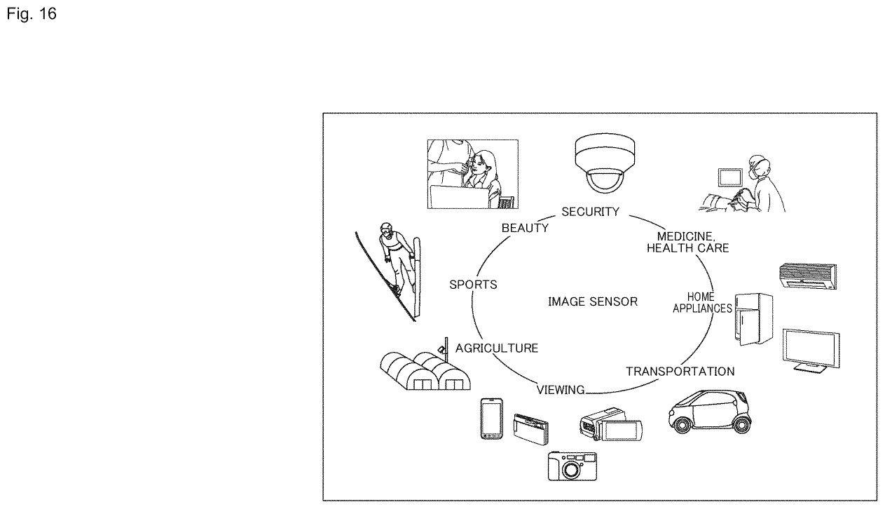

FIG. 16 is a diagram illustrating an example of how an image sensor including the solid-state image capturing device 200 is used.

An image sensor including the solid-state image capturing device 200 described above can be used in various cases for sensing light such as visible light, infrared light, ultraviolet light, and X-rays, for example, as will be described below.
Devices that capture images used for viewing, such as digital cameras and mobile devices with camera functions
Devices used for transportation, such as in-vehicle sensors that capture front, rear, peripheral, and interior view images of automobiles, monitoring cameras that monitor traveling vehicles and roads, range sensors that measure distances between vehicles, and the like, for driving safety features such as automatic stopping, recognizing the state of the driver, and the like
Devices used for home appliances such as TVs, refrigerators, and air conditioners in order to capture images of gestures made by a user and operate the devices in accordance with the gestures
Devices used in medicine and healthcare, such as endoscopes and devices that perform angiography by receiving infrared light
Devices used for security, such as surveillance cameras for crime prevention and cameras for personal authentication
Devices used in beauty applications, such as skin measuring devices that capture images of the skin and microscopes that capture images of the scalp
Devices used for sports, such as action cameras and wearable cameras for sports applications.
Devices used for agriculture, such as cameras for monitoring the states of fields and crops

### 12. Application in Light Detection Devices in General

Although the foregoing examples described the technique of the present disclosure being applied in a solid-state image capturing device that outputs an image signal, the technique of the present disclosure can be applied not only in such solid-state image capturing devices, but also in any light detection device that includes pixels which receive incident light and photoelectrically convert the light. For example, the technique of the present disclosure can also be applied in a light receiving device (a range sensor) of a rangefinding system that receives infrared light emitted as active light and measures a distance to a subject by a direct ToF method or an indirect ToF method. The technique is also not limited to a CMOS-type solid-state image capturing device, and can also be applied in a Charge Coupled Device (CCD)-type solid-state image capturing device.

### 13. Example of Application in Endoscopic Surgery System

The technique according to the present disclosure (the present technique) can be applied in various products. For example, the technique according to the present disclosure may be applied in an endoscopic surgery system.

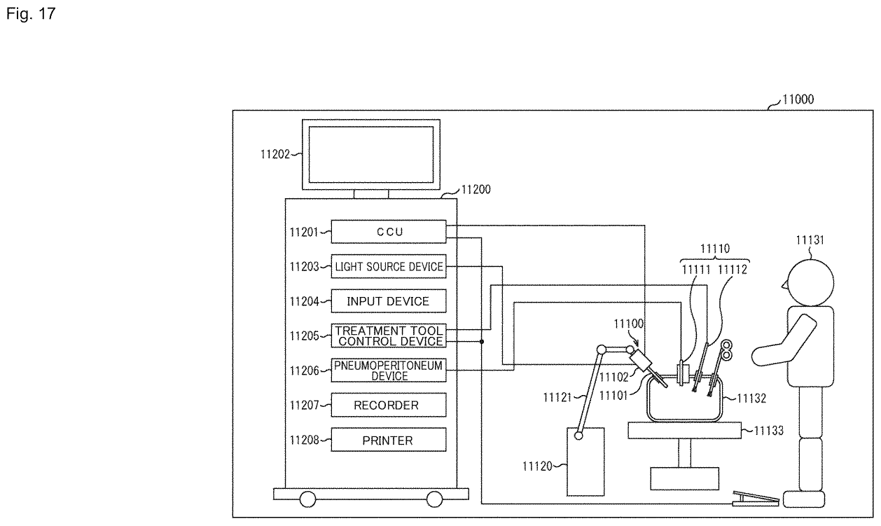

FIG. 17 is a diagram illustrating an example of the schematic configuration of an endoscopic surgery system to which the technique according to the present disclosure (the present technique) is applied.

FIG. 17 illustrates a state where an operator (doctor) 11131 is using an endoscopic surgery system 11000 to perform a surgical operation on a patient 11132 laying on a patient bed 11133. As illustrated here, the endoscopic surgery system 11000 is constituted by an endoscope 11100, another surgical instrument 11110 such as a pneumoperitoneum tube 11111 or an energized treatment tool 11112, a support arm device 11120 that supports the endoscope 11100, and a cart 11200 mounted with various devices for endoscopic surgery.

The endoscope 11100 includes a lens barrel 11101, of which a region having a predetermined length from a tip thereof is inserted into a body cavity of the patient 11132, and a camera head 11102 connected to a base end of the lens barrel 11101. In the example illustrated here, the endoscope 11100 is configured as what is known as a rigid endoscope having a rigid lens barrel 11101, but the endoscope 11100 may be configured as what is known as a flexible endoscope having a flexible lens barrel.

The tip of the lens barrel 11101 is provided with an opening into which an objective lens is fitted. A light source device 11203 is connected to the endoscope 11100, light generated by the light source device 11203 is guided to the tip of the lens barrel 11101 by a light guide provided extending along the inside of the lens barrel 11101, and the light is emitted toward an observation target in the body cavity of the patient 11132 through the objective lens. The endoscope 11100 may be a direct-view endoscope, an oblique-view endoscope, or a side-view endoscope.

An optical system and an image sensor are provided inside of the camera head 11102, and reflected light (observation light) from the observation target is focused on the image sensor by the optical system. The observation light is photoelectrically converted by the image sensor, and an electrical signal corresponding to the observation light, i.e., an image signal corresponding to an observation image, is generated. The image signal is transmitted to a camera control unit (CCU) 11201 as RAW data.

The CCU 11201 is constituted by a central processing unit (CPU), a graphics processing unit (GPU), and the like, and comprehensively controls the operations of the endoscope 11100 and a display device 11202. In addition, the CCU 11201 receives an image signal from the camera head 11102 and performs various types of image processing on the image signal to display an image based on the image signal, such as, for example, development processing (demosaicing) and the like.

The display device 11202 displays the image based on the image signal subjected to the image processing by the CCU 11201 under the control of the CCU 11201.

The light source device 11203 is constituted by, for example, a light source such as a Light Emitting Diode (LED), and supplies the endoscope 11100 with emitted light when capturing an image of a surgical site or the like.

An input device 11204 is an input interface for the endoscopic surgery system 11000. The user can input various types of information or instructions to the endoscopic surgery system 11000 through the input device 11204. For example, the user inputs an instruction to change image capturing conditions (the type of emitted light, the magnification, the focal length, or the like) of the endoscope 11100.

A treatment tool control device 11205 controls driving of the energized treatment tool 11112 for the cauterization or incision of tissues, sealing blood vessels, or the like. The pneumoperitoneum device 11206 sends a gas into the body cavity of the patient 11132 through the pneumoperitoneum tube 11111 in order to inflate the body cavity and secure a field of view for the endoscope 11100 and a working space of the operator. A recorder 11207 is a device capable of recording various types of information pertaining to the surgery. A printer 11208 is a device capable of printing various types of information pertaining to the surgery in various formats such as text, images, and graphs.

The light source device 11203 that supplies the endoscope 11100 with the emitted light for capturing images of the surgical site can be constituted by, for example, an LED, a laser light source, or a white light source constituted by a combination thereof. When a white light source is constituted by a combination of RGB laser light sources, the output intensity and the output timing of each color (each wavelength) can be controlled with high accuracy, and thus the light source device 11203 can adjust the white balance of the captured image. In this case, by irradiating the observation target with laser light from each of the RGB laser light sources in time-division and controlling the driving of the image sensor in the camera head 11102 in synchronization with that irradiation timing, images corresponding to each of the RGB colors can be captured in time-division as well. According to this method, color images can be obtained even without providing the image sensor with a color filter.

In addition, the driving of the light source device 11203 may be controlled to change the intensity of the output light every predetermined interval. By controlling the driving of the image sensor of the camera head 11102 and obtaining an image through time division in synchronization with the timing at which the intensity of the light is changed, and then compositing those images, a high dynamic range image without blocked-up shadows or blowouts can be generated.

The light source device 11203 may be configured to be capable of supplying light in a predetermined wavelength band corresponding to special light observation. In the special light observation, for example, by emitting light in a band narrower than that of emitted light during normal observation (that is, white light) using wavelength dependence of light absorption in a body tissue, what is known as narrow band light observation (narrow band imaging) in which a predetermined tissue such as a blood vessel in a mucous membrane surface layer is imaged with a high contrast is performed. Alternatively, in special light observation, fluorescence observation may be used to obtain an image from fluorescence generated by emitting excitation light. In fluorescence observation, body tissue is irradiated with excitation light and the fluorescence from the body tissue is observed (autofluorescence observation), or a reagent such as indocyanine green (ICG) is injected into the body tissue and the tissue is irradiated with excitation light corresponding to the fluorescence wavelength of the reagent to obtain a fluorescent image. The light source device 11203 can be configured to supply narrow band and/or excitation light corresponding to such special light observation.

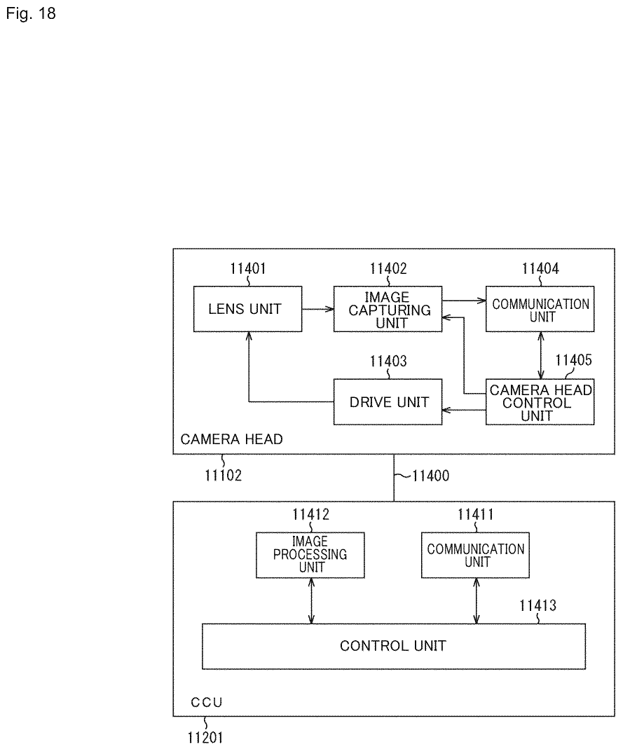

FIG. 18 is a block diagram illustrating an example of functional configurations of the camera head 11102 and the CCU 11201 illustrated in FIG. 17.

The camera head 11102 includes a lens unit 11401, an image capturing unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection part for connection to the lens barrel 11101. Observation light taken in from the tip of the lens barrel 11101 is guided to the camera head 11102 and is incident on the lens unit 11401. The lens unit 11401 is configured as a combination of a plurality of lenses including a zoom lens and a focus lens.

The image capturing unit 11402 is constituted by an image sensor. The image sensor constituting the image capturing unit 11402 may be a single element (what is known as a single plate type) or a plurality of elements (what is known as a multi-plate type). When the image capturing unit 11402 is configured as a multi-plate type, for example, image signals corresponding to each color of R, G, and B may be generated by the image sensors, and a color image may be obtained by compositing the image signals. Alternatively, the image capturing unit 11402 may be configured to include a pair of image sensors for obtaining image signals for the right eye and the left eye, respectively, so as to implement a three-dimensional (3D) display. Implementing a 3D display enables the operator 11131 to ascertain the depth of biological tissues in the surgical site more accurately. When the image capturing unit 11402 is configured as a multi-plate type, a plurality of lens units 11401 may be provided so as to correspond to the respective image sensors.

The image capturing unit 11402 does not necessarily have to be provided in the camera head 11102. For example, the image capturing unit 11402 may be provided immediately after the objective lens inside of the lens barrel 11101.

The drive unit 11403 is constituted by an actuator, and the zoom lens and the focus lens of the lens unit 11401 are moved by a predetermined distance along an optical axis under the control of the camera head control unit 11405. The magnification and focus of the image captured by the image capturing unit 11402 can therefore be adjusted appropriately.

The communication unit 11404 is constituted by a communication device for exchanging various types of information with the CCU 11201. The communication unit 11404 transmits the image signal obtained from the image capturing unit 11402 as RAW data to the CCU 11201 over the transmission cable 11400.

The communication unit 11404 receives a control signal for controlling the driving of the camera head 11102 from the CCU 11201 and supplies that control signal to the camera head control unit 11405. The control signal includes, for example, information regarding image capturing conditions, such as information indicating a designation of a framerate of a captured image, information indicating a designation of an exposure value when an image is captured, and/or information indicating a designation of the magnification and the focus of the captured image.

The image capturing conditions such as the framerate, the exposure value, the magnification, and the focus may be designated by the user as appropriate, or may be automatically set by the control unit 11413 of the CCU 11201 based on the obtained image signal. In the latter case, what are known as an auto exposure (AE) function, an auto focus (AF) function, and an auto white balance (AWB) function are provided in the endoscope 11100.

The camera head control unit 11405 controls the driving of the camera head 11102 based on a control signal from the CCU 11201 received via the communication unit 11404.

The communication unit 11411 is constituted by a communication device that exchanged various kinds of information with the camera head 11102. The communication unit 11411 receives an image signal transmitted over the transmission cable 11400 from the camera head 11102.

The communication unit 11411 also transmits control signals for controlling the driving of the camera head 11102 to the camera head 11102. The image signals and the control signals can be transmitted through electric communication, optical communication, or the like.

The image processing unit 11412 performs various types of image processing on the image signal that is the RAW data transmitted from the camera head 11102.

The control unit 11413 performs various types of control pertaining to capturing images of a surgical site by the endoscope 11100, displaying captured images obtained by capturing images of a surgical site, or the like. For example, the control unit 11413 generates control signals for controlling the driving of the camera head 11102.

In addition, the control unit 11413 causes the display device 11202 to display a captured image showing a surgical site or the like based on an image signal subjected to the image processing by the image processing unit 11412. At this time, the control unit 11413 may recognize various objects in the captured image using various image recognition techniques. For example, the control unit 11413 can recognize a surgical instrument such as forceps, a specific biological site, bleeding, mist or the like produced when using the energized treatment tool 11112, or the like by detecting a shape, a color, or the like of an edge of an object present in the captured image. When causing the display device 11202 to display a captured image, the control unit 11413 may superimpose various types of surgery support information on an image of the surgical site for display using a result of the recognition. Displaying the surgery support information in a superimposed manner and presenting that information to the operator 11131 makes it possible to lighten the burden on the operator 11131 and enable the operator 11131 to proceed with the surgery with confidence.

The transmission cable 11400 that connects the camera head 11102 and the CCU 11201 is an electrical signal cable that supports communication of electrical signals, an optical fiber that supports optical communication, or a composite cable thereof.

Although wired communication is performed using the transmission cable 11400 in the example illustrated here, the camera head 11102 and the CCU 11201 may communicate wirelessly.

An example of an endoscopic surgery system to which the technique according to the present disclosure can be applied has been described thus far. The technique according to the present disclosure may be applied to the image capturing unit 11402 of the camera head 11102 among the configurations described above. Specifically, the solid-state image capturing device 200 illustrated in FIG. 14 can be applied as the image capturing unit 11402, for example. Applying the technique according to the present disclosure to the image capturing unit 11402 makes it possible to obtain a clearer image of the surgical site while at the same time reducing the size of the camera head 11102.

Here, although an endoscopic surgery system has been described as an example, the technique according to the present disclosure may be applied to other systems, such as a microscopic surgery system, for example.

### 14. Example of Application in Moving Body

The technique according to the present disclosure (the present technique) can be applied in various products. For example, the technique according to the present disclosure may be realized as a device mounted on any type of moving body such as an automobile, an electric automobile, a hybrid electric automobile, a motorcycle, a bicycle, a personal mobility device, an airplane, a drone, a ship, a robot, or the like.

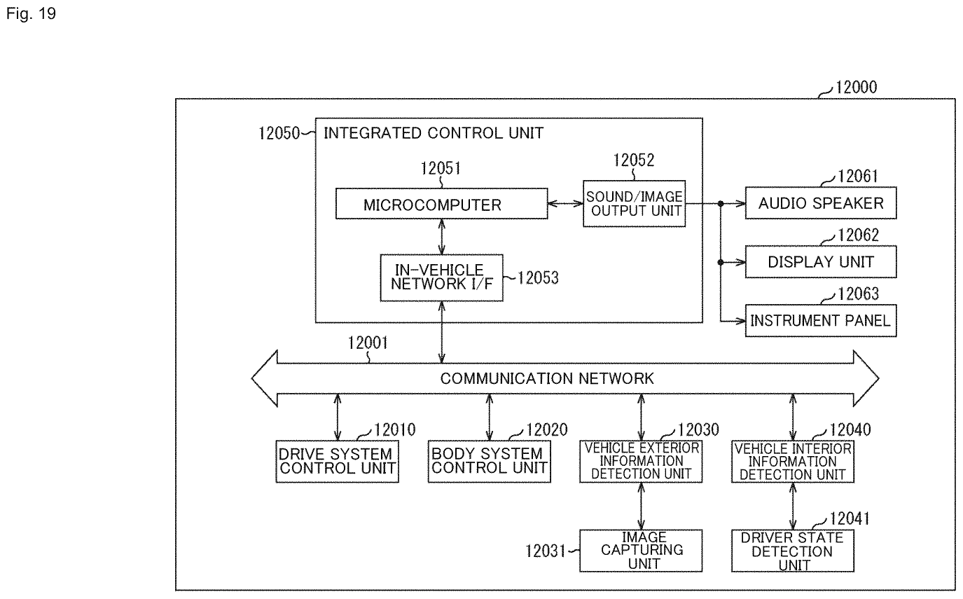

FIG. 19 is a block diagram schematically illustrating an example of the configuration example of a vehicle control system, which is an example of a moving body control system to which the technique according to the present disclosure can be applied.

A vehicle control system 12000 includes a plurality of electronic control units connected over a communication network 12001. In the example illustrated in FIG. 19, the vehicle control system 12000 includes a drive system control unit 12010, a body system control unit 12020, a vehicle exterior information detection unit 12030, a vehicle interior information detection unit 12040, and an integrated control unit 12050. In addition, a microcomputer 12051, a sound/image output unit 12052, and an in-vehicle network interface (I/F) 12053 are illustrated as functional configurations of the integrated control unit 12050.

The drive system control unit 12010 controls operations of devices related to a drive system of the vehicle according to various types of programs. For example, the drive system control unit 12010 functions as control devices, such as a driving force generation device for generating driving force for the vehicle, such as an internal combustion engine or a driving motor; a driving force transmission mechanism for transmitting driving force to wheels; a steering mechanism for adjusting a turning angle of the vehicle; a braking device that generates braking force for the vehicle; and the like.

The body system control unit 12020 controls the operations of various devices mounted in the vehicle body in accordance with various programs. For example, the body system control unit 12020 functions as control devices for a keyless entry system, a smart key system, power window devices, or various lamps such as headlights, backup lights, brake lights, turn signals, fog lights, and the like. In this case, radio waves emitted from a portable device that substitutes for a key or signals from various switches can be input to the body system control unit 12020. The body system control unit 12020 receives the input of the radio waves or signals and controls door lock devices, power window devices, the lamps, and the like of the vehicle.

The vehicle exterior information detection unit 12030 detects information on the exterior of the vehicle in which the vehicle control system 12000 is installed. For example, an image capturing unit 12031 is connected to the vehicle exterior information detection unit 12030. The vehicle exterior information detection unit 12030 causes the image capturing unit 12031 to capture an image of the exterior of the vehicle, and receives the captured image. The vehicle exterior information detection unit 12030 may perform object detection processing or distance detection processing for people, cars, obstacles, signs, letters on the road, and the like based on the received image.

The image capturing unit 12031 is an optical sensor that receives light and outputs an electrical signal according to the intensity of the received light. The image capturing unit 12031 can also output the electrical signal as an image or as distance measurement information. In addition, the light received by the image capturing unit 12031 may be visible light or non-visible light such as infrared light.

The vehicle interior information detection unit 12040 detects information on the interior of the vehicle. For example, a driver state detection unit 12041 that detects a state of a driver is connected to the vehicle interior information detection unit 12040. The driver state detection unit 12041 includes, for example, a camera that captures an image of the driver, and the vehicle interior information detection unit 12040 may calculate the level of the driver's fatigue or concentration, or may determine whether the driver is dozing, based on detection information input from the driver state detection unit 12041.

For example, the microcomputer 12051 can calculate control target values for a driving force generation device, a steering mechanism, or a braking device based on information on the inside and outside of the vehicle obtained by the vehicle exterior information detection unit 12030 and the vehicle interior information detection unit 12040, and output control commands to the drive system control unit 12010. For example, the microcomputer 12051 can perform coordinated control for the purpose of implementing functions of an Advanced Driver Assistance System (ADAS) including vehicle collision avoidance, impact mitigation, following traveling based on an inter-vehicle distance, constant vehicle speed driving, vehicle collision warnings, and lane departure warnings.

In addition, the microcomputer 12051 can perform coordinated control for the purpose of automated driving or the like in which autonomous travel is performed without requiring operations of the driver, by controlling the driving force generation device, the steering mechanism, the braking device, or the like based on information about the surroundings of the vehicle, the information being obtained by the vehicle exterior information detection unit 12030 or the vehicle interior information detection unit 12040.

In addition, the microcomputer 12051 can output control commands to the body system control unit 12020 based on the information on the exterior of the vehicle obtained by the vehicle exterior information detection unit 12030. For example, the microcomputer 12051 can perform coordinated control for the purpose of suppressing glare, such as switching from high beams to low beams by controlling the headlights according to the position of a preceding vehicle or an oncoming vehicle detected by the vehicle exterior information detection unit 12030.

The sound/image output unit 12052 transmits an output signal of at least one of sound and an image to an output device capable of visually or audibly providing information to an occupant or to the exterior of the vehicle. In the example illustrated in FIG. 19, an audio speaker 12061, a display unit 12062, and an instrument panel 12063 are illustrated as examples of the output device. The display unit 12062 may include at least one of an on-board display and a heads-up display, for example.

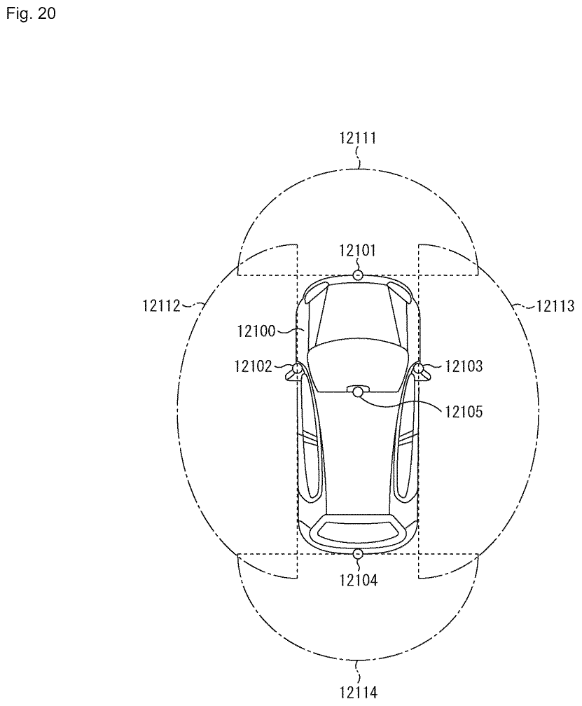

FIG. 20 is a diagram illustrating an example of an installation position of the image capturing unit 12031.

In FIG. 20, a vehicle 12100 includes image capturing units 12101, 12102, 12103, 12104, and 12105 as the image capturing unit 12031.

The image capturing units 12101, 12102, 12103, 12104, and 12105 are provided at the positions of the front nose, the side-view mirrors, the rear bumper, the trunk door, an upper part of the windshield within the vehicle cabin, and the like of the vehicle 12100, for example. The image capturing unit 12101 provided on the front nose and the image capturing unit 12105 provided in an upper part of the windshield within the vehicle cabin mainly obtain images from in front of the vehicle 12100. The image capturing units 12102 and 12103 provided in the side-view mirrors mainly obtain images from the sides of the vehicle 12100. The image capturing unit 12104 provided on the rear bumper or the trunk door mainly obtains images of an area behind the vehicle 12100. The images obtained by the image capturing units 12101 and 12105 are mainly used for detecting preceding vehicles, pedestrians, obstacles, traffic signals, traffic signs, lanes, and the like.

FIG. 20 illustrates an example of image capturing ranges of the image capturing units 12101 to 12104. An image capturing range 12111 indicates an image capturing range of the image capturing unit 12101 provided on the front nose; image capturing ranges 12112 and 12113 respectively indicate the image capturing ranges of the image capturing units 12102 and 12103 provided in the side-view mirrors; and an image capturing range 12114 indicates the image capturing range of the image capturing unit 12104 provided on the rear bumper or the trunk door. For example, by superimposing image data captured by the image capturing units 12101 to 12104, it is possible to obtain a bird's-eye view image seen from above the vehicle 12100.

At least one of the image capturing units 12101 to 12104 may have a function for obtaining distance information. For example, at least one of the image capturing units 12101 to 12104 may be a stereo camera constituted by a plurality of image sensors, or may be an image sensor that has pixels for phase difference detection.

For example, the microcomputer 12051 can extract, particularly, a closest three-dimensional object on a path through which the vehicle 12100 is traveling, which is a three-dimensional object traveling at a predetermined speed (for example, at least 0 km/h) in substantially the same direction as the vehicle 12100, as a preceding vehicle by obtaining a distance to each three-dimensional object in the image capturing ranges 12111 to 12114 and temporal changes in the distance (a relative speed with respect to the vehicle 12100) based on distance information obtained from the image capturing units 12101 to 12104. The microcomputer 12051 can also set an inter-vehicle distance to the preceding vehicle to be maintained in advance and perform automatic brake control (including following stop control) and automatic acceleration control (including following start control). It is therefore possible to perform coordinated control for the purpose of, for example, automated driving in which the vehicle travels in an automated manner without requiring the driver to perform operations.

For example, the microcomputer 12051 can classify and extract three-dimensional data regarding three-dimensional objects as two-wheeled vehicles, normal vehicles, large vehicles, pedestrians, and other three-dimensional objects such as electrical poles based on the distance information obtained from the image capturing units 12101 to 12104, and can use the three-dimensional data to automatically avoid obstacles. For example, the microcomputer 12051 classifies obstacles around the vehicle 12100 into obstacles visible to the driver of the vehicle 12100 and obstacles which are difficult to see. Then, the microcomputer 12051 determines a collision risk indicating the degree of risk of collision with each obstacle, and when the collision risk is at least a set value and there is a possibility of collision, an alarm is output to the driver through the audio speaker 12061 or the display unit 12062, forced deceleration or avoidance steering is performed through the drive system control unit 12010, and the like, making it possible to provide driving assistance for collision avoidance.

At least one of the image capturing units 12101 to 12104 may be an infrared camera that detects infrared rays. For example, the microcomputer 12051 can recognize a pedestrian by determining whether there is a pedestrian in an image captured by the image capturing units 12101 to 12104. Such pedestrian recognition is performed by, for example, a sequence in which feature points in the images captured by the image capturing units 12101 to 12104 as infrared cameras are extracted and a sequence in which pattern matching processing is performed on a series of feature points indicating an outline of an object to determine whether the object is a pedestrian. When the microcomputer 12051 determines that there is a pedestrian in the image captured by the image capturing units 12101 to 12104 and the pedestrian is recognized, the sound/image output unit 12052 controls the display unit 12062 such that a quadrangular frame for emphasis is superimposed on and displayed with the recognized pedestrian. In addition, the sound/image output unit 12052 may control the display unit 12062 such that an icon indicating a pedestrian or the like is displayed at a desired position.

An example of the vehicle control system to which the technique according to the present disclosure can be applied has been described thus far. The technique according to the present disclosure may be applied to the image capturing unit 12031 and the like among the above-described configurations. Specifically, the solid-state image capturing device 200 illustrated in FIG. 14 can be applied as the image capturing unit 12031, for example. Applying the technique of the present disclosure to the image capturing unit 12031 makes it possible to obtain a clearer captured image and obtain distance information while at the same time reducing the size of the unit. In addition, using the obtained shot image and the distance information makes it possible to reduce driver fatigue and increase the safety for the driver and the vehicle.

The embodiments of the present disclosure are not limited to the above-described embodiments, and various modifications can be made without departing from the essential spirit of the technique of the present disclosure.

The advantageous effects described in the present specification are merely exemplary and are not limited, and other advantageous effects of the advantageous effects described in the present specification may be achieved.

The technique of the present disclosure can be configured as follows.

(1)

A light detection device including:
a pixel array unit in which a plurality of pixels is arranged in a two-dimensional array, each pixel including:
a refractive index variation layer having at least two regions in the same layer, the two regions being a first region containing a first matter and a second region containing a second matter; and
a photoelectric conversion unit that photoelectrically converts light incident through the refractive index variation layer,
wherein an effective refractive index of the refractive index variation layer is configured to differ depending on an image height position of the pixel.
   (2)

The light detection device according to (1),
wherein an area ratio between the first region and the second region of the refractive index variation layer is configured to differ depending on the image height position of the pixel.
   (3)

The light detection device according to (2),
wherein the effective refractive index of the refractive index variation layer in the pixel at a high image height position is configured to be higher than the effective refractive index of the refractive index variation layer in the pixel at a position near a center of the image height.
   (4)

The light detection device according to (2) or (3),
wherein the area ratio between the first region and the second region is configured to also differ along a thickness direction of the refractive index variation layer.
   (5)

The light detection device according to any one of (1) to (4),
wherein one of a size, a pitch, or a shape of a pattern of the second region formed within the first region of the refractive index variation layer is configured to differ depending on the image height position of the pixel.
   (6)

The light detection device according to any one of (1) to (5),
wherein each pixel further includes an anti-reflection film formed from a plurality of films including a first film containing the first matter and a second film containing the second matter, the anti-reflection film being formed on an upper surface of a semiconductor substrate in which the photoelectric conversion unit is formed, and
the refractive index variation layer is configured by embedding the second film, which is an upper layer, in the first film, which is a lower layer.
   (7)

The light detection device according to (6),
wherein a refractive index of the first film in the lower layer is higher than a refractive index of the second film in the upper layer.
   (8)

The light detection device according to (6) or (7),
wherein the anti-reflection film is constituted by three layers, the three layers being the first film in an intermediate layer, the second film in an uppermost layer, and a third film in a lowermost layer, and a refractive index of the second film is higher than a refractive index of the first film and a refractive index of the third film.
   (9)

The light detection device according to any one of (1) to (8), further including:
an anti-reflection film constituted by a plurality of films, the anti-reflection film being formed on an upper surface of a semiconductor substrate in which the photoelectric conversion unit is formed,
wherein the first region is a region in which the photoelectric conversion unit is formed, and
the second region is a region in which the anti-reflection film is formed.
   (10)

The light detection device according to any one of (1) to (8),
wherein the pixel further includes an on-chip lens, and the refractive index variation layer is formed on an upper surface of the on-chip lens.
   (11)

The light detection device according to any one of (1) to (8),
wherein the pixel further includes a color filter layer, and the refractive index variation layer is formed on an upper surface of the color filter layer.
   (12)

The light detection device according to any one of (1) to (11),
wherein the pixel further includes a color filter layer, and the effective refractive index of the refractive index variation layer is configured to also differ depending on a color of the color filter layer.
   (13)

The light detection device according to any one of (1) to (12),
wherein one on-chip lens is provided for a plurality of the pixels, and the effective refractive index of the refractive index variation layer is configured to also differ for each of the pixels below the one on-chip lens.
   (14)

The light detection device according to any one of (1) to (13),
wherein the photoelectric conversion unit is formed on a semiconductor substrate constituted by any one material among Si, Ge, SiGe, GaAs, InGaAs, InGaAsP, InAs, InSb, or InAsSb.
   (15)

An electronic device including a light detection device,
wherein the light detection device includes a pixel array unit in which a plurality of pixels is arranged in a two-dimensional array, each pixel including:
a refractive index variation layer having at least two regions in the same layer, the two regions being a first region containing a first matter and a second region containing a second matter; and
a photoelectric conversion unit that photoelectrically converts light incident through the refractive index variation layer, and
wherein an effective refractive index of the refractive index variation layer is configured to differ depending on an image height position of the pixel.

### REFERENCE SIGNS LIST

10 Pixel
11 Photodiode
20 Semiconductor substrate
21 Pixel separation part
22 Anti-reflection film
23 Inter-pixel light shielding film
24 Color filter layer
25 On-chip lens
31 Aluminum oxide film
32 Titanium oxide film
33 Silicon oxide film
34 Refractive index variation layer
50 Pixel array unit
90 Anti-reflection film
91 First film
92 Second film
100 Anti-reflection film
101 First film
102 Second film
121 On-chip lens
200 Solid-state image capturing device
202 Pixel
203 Pixel array unit
300 Image capturing device
302 Solid-state image capturing device

1. A light detection device comprising:
a pixel array unit in which a plurality of pixels is arranged in a two-dimensional array, each pixel including:
a refractive index variation layer having at least two regions in the same layer, the two regions being a first region containing a first matter and a second region containing a second matter; and
a photoelectric conversion unit that photoelectrically converts light incident through the refractive index variation layer,
wherein an effective refractive index of the refractive index variation layer is configured to differ depending on an image height position of the pixel.

2. The light detection device according to claim 1,
wherein an area ratio between the first region and the second region of the refractive index variation layer is configured to differ depending on an image height position of the pixel.

3. The light detection device according to claim 2,
wherein the effective refractive index of the refractive index variation layer in the pixel at a high image height position is configured to be higher than the effective refractive index of the refractive index variation layer in the pixel at a position near a center of the image height.

4. The light detection device according to claim 2,
wherein the area ratio between the first region and the second region is configured to also differ along a thickness direction of the refractive index variation layer.

5. The light detection device according to claim 1,
wherein one of a size, a pitch, or a shape of a pattern of the second region formed within the first region of the refractive index variation layer is configured to differ depending on the image height position of the pixel.

6. The light detection device according to claim 1,
wherein each pixel further includes an anti-reflection film formed from a plurality of films including a first film containing the first matter and a second film containing the second matter, the anti-reflection film being formed on an upper surface of a semiconductor substrate in which the photoelectric conversion unit is formed, and
the refractive index variation layer is configured by embedding the second film, which is an upper layer, in the first film, which is a lower layer.

7. The light detection device according to claim 6,
wherein a refractive index of the first film in the lower layer is higher than a refractive index of the second film in the upper layer.

8. The light detection device according to claim 6,
wherein the anti-reflection film is constituted by three layers, the three layers being the first film in an intermediate layer, the second film in an uppermost layer, and a third film in a lowermost layer, and
a refractive index of the second film is higher than a refractive index of the first film and a refractive index of the third film.

9. The light detection device according to claim 1, further comprising:
an anti-reflection film constituted by a plurality of films, the anti-reflection film being formed on an upper surface of a semiconductor substrate in which the photoelectric conversion unit is formed,
wherein the first region is a region in which the photoelectric conversion unit is formed, and
the second region is a region in which the anti-reflection film is formed.

10. The light detection device according to claim 1,
wherein the pixel further includes an on-chip lens, and
the refractive index variation layer is formed on an upper surface of the on-chip lens.

11. The light detection device according to claim 1,
wherein the pixel further includes a color filter layer, and
the refractive index variation layer is formed on an upper surface of the color filter layer.

12. The light detection device according to claim 1,
wherein the pixel further includes a color filter layer, and
the effective refractive index of the refractive index variation layer is configured to also differ depending on a color of the color filter layer.

13. The light detection device according to claim 1,
wherein one on-chip lens is provided for a plurality of the pixels, and
the effective refractive index of the refractive index variation layer is configured to also differ for each of the pixels below the one on-chip lens.

14. The light detection device according to claim 1,
wherein the photoelectric conversion unit is formed on a semiconductor substrate constituted by any one material among Si, Ge, SiGe, GaAs, InGaAs, InGaAsP, InAs, InSb, or InAsSb.

15. An electronic device comprising a light detection device,
wherein the light detection device includes a pixel array unit in which a plurality of pixels is arranged in a two-dimensional array, each pixel including:
a refractive index variation layer having at least two regions in the same layer, the two regions being a first region containing a first matter and a second region containing a second matter; and
a photoelectric conversion unit that photoelectrically converts light incident through the refractive index variation layer, and
wherein an effective refractive index of the refractive index variation layer is configured to differ depending on an image height position of the pixel.
